(19) United States
(12) Patent Application Publication
(10) Pub. No.: US 2026/0237929 A1
(43) Pub. Date: Aug. 13, 2026

(54) Tamper-proof Electrical Outlet Assembly and Method thereof

(71) Applicant: Transtech Innovations inc., Varennes (CA)

(72) Inventors: Joel Martin, Varennes (CA); Pier-Luc Cote, Varennes (CA)

(21) Appl. No.: 19/181,258

(22) Filed: Apr. 16, 2025

Related U.S. Application Data
(60) Provisional application No. 63/634,726, filed on Apr. 16, 2024.

(51) Int. Cl. H01R 13/10; H01R 13/514; H01R 13/66; H01R 25/00

(52) U.S. Cl. CPC H01R 13/10; H01R 13/514; H01R 13/6683; H01R 13/6691; H01R 25/003

(57) ABSTRACT

This vandal-proof modular power outlet assembly presents an adaptable solution for electrical power distribution in public, commercial, and domestic settings. Featuring a main body housing one or more outlet receptacles and an electrical core, the assembly ensures resistance to vandalism and environmental factors. Removable connector blocks, securely trapped within the receptacles, may offer standard electrical and USB sockets, facilitating easy maintenance and accommodating diverse user needs. This innovation addresses the pressing demand for reliable and tamper-resistant electrical infrastructure, setting a new standard for modular power outlets in modern infrastructure.

### CROSS-REFERENCE TO RELATED APPLICATIONS

The present patent application claims the benefits of priority of United States Provisional Patent Application No. 63/634,726, entitled "MODULAR ELECTRICAL OUTLET ASSEMBLY AND METHOD THEREOF", and filed at the United States Patent and Trademark Office on April 16, 2024, the content of which is incorporated herein by reference.

### FIELD OF THE INVENTION

The present invention generally relates to the field of modular electrical power outlets and method for using the same. More specifically, the present invention relates to modular electrical power outlets increasing protection against vandalism acts and for providing modular smart electrical power outlets.

### BACKGROUND OF THE INVENTION

Electrical outlets are ubiquitous components of modern infrastructure, facilitating the connection of various electrical devices to power sources. Traditional electrical outlets, while functional, often lack proofing against intentional or accidental damage, particularly in high-traffic or exposed environments. Instances of vandalism, tampering, or misuse of electrical outlets can result in safety hazards, damage to property, and disruption of electrical service. Thus, there exists a pressing demand for innovative solutions that enhance the durability, security, and longevity of electrical outlets while maintaining their functionality and convenience.

In contemporary settings such as public spaces, transportation hubs, educational institutions, and commercial facilities, the reliability and safety of electrical outlets are paramount. However, conventional outlets are susceptible to damage from physical impact, unauthorized access, and exposure to environmental elements. Vandalism, including deliberate attempts to disable or destroy outlets, poses significant challenges for facility managers, property owners, and municipal authorities. Such vandalism acts may include filing contact openings with gums or other soft material, inserting metallic objects into contact openings or tampering with the electrical outlet. Additionally, accidental damage caused by routine maintenance, cleaning procedures, or everyday use can necessitate frequent repairs or replacements, leading to operational inefficiencies and increased maintenance costs. Furthermore, other misuse may include inserting a metallic object, such as a paper clip, in the live and neutral sockets to trigger the breaker. As such, there is a clear need within the field for innovative solutions that mitigate these concerns and offer robust, vandal-proof alternatives to conventional electrical outlets.

Even though modular power outlets, in which the socket can be removed and replaced, are already well known in the field of power outlets, there is still a need for a modular power outlet assembly that is vandal-proof and that can be easily maintained, cleaned or restored without having to completely replace the socket.

### SUMMARY OF THE INVENTION

The shortcomings of the prior art are generally mitigated by a vandal-proof modular power outlet assembly as described hereinafter.

The present invention consists of a main body housing an outlet receptacle, a durable upper portion, and a narrower bottom portion housing an electrical core portion, the assembly is engineered to withstand vandalism and environmental challenges. Resilient members within the receptacle secure removable connector blocks, facilitating easy cleaning and maintenance. Connector blocks provide standard electrical and USB sockets, catering to various user needs, while alternative blocks may offer functionalities like intercom systems or RFID readers for device identification and consumption monitoring.

In an aspect of the invention, a modular power outlet assembly is provided. The assembly comprises a recess portion, the recess portion comprising resilient connectors powered by an electrical current and a modular electrical receptacle adapted to be removably received by the recess portion, the modular electrical receptacle comprising passages adapted to receive contacts of an electrical contacts to contact the resilient connectors.

The modular electrical receptacle may comprise a low voltage connector adapted to receive a portion of the electrical contacts of an electric plug. The low voltage connector may be used as an electronic child-proof protection.

The modular power outlet assembly may comprise a top covering portion attachable to an electrical outlet box. The top covering portion may comprise a processor programmed to provide special features. The top covering portion may comprise a wireless communication module. The wireless communication module may be a WI-FI module configured as a repeater to a local or remote network. The wireless communication module may be a Bluetooth^{TM} module configured as a repeater to a local or remote network.

In another aspect of the invention, a tamper-proof electrical outlet assembly is provided. The electrical outlet assembly comprises a controller, a base portion comprising at least two electrical connectors connected to an operative voltage source and an electrical outlet comprising at least two passages, each passage comprising a conductive portion connected to the electrical connectors and connected to the controller. The controller is configured to detect insertion of any of the blades of an electric plug in one of the passages of the electrical outlet and insertion of two blades of an electric plug in two of the passages of the electrical outlet. The controller is further configured to power the two electrical connectors with the operative voltage when insertion of two blades of an electric plug is detected.

The electrical outlet assembly may further comprise an electric relay connected to the controller and the electrical connectors, the relay being operable to supply the operative voltage to the two electrical connectors when the insertion of two blades of an electric plug is detected.

The controller may be configured to measure impedance in the conductive portion of the electrical outlet and to power the two electrical connectors when the measured impedance varies from a predetermined impedance level. The conductive portion of each opening may comprise a top section and a bottom section, the controller may further be configured to detect depth of insertion of a blade of an electric plug based on detected presence of the blade over the top and bottom sections.

The electrical connectors and the conductive portions may be curved conductive plates.

The base portion may comprise a recess comprising the electrical connectors, the electrical outlet being a removable module having a shape substantially matching a shape of the recess. The removable module may comprise at least two passages for receiving prongs of an electrical plug and shaped to allow contact of the receivable prongs with the electrical connectors and with the conductive portions. The removable module may comprise a body having recesses for allowing passage of the electrical connectors of the recess. The removable module may be retained within the recess of the body by friction or locking engagement. The removable module may comprise a speaker and a microphone. The modular receptacle may comprise an RFID reader and is configured to detect a plug having an RFID tag.

The electrical outlet assembly may further comprise a top covering portion mountable to an electrical box, the top covering portion defining at least one receptacle opening. The modular electrical outlet assembly may further comprise a bracket configured to mount the assembly to a bench, seat, or surface, the bracket comprising fastener apertures and a recess for receiving wires or may further comprise a wireless communication module configured as a network repeater.

In another aspect of the invention, a modular connector removably insertable in an electrical outlet assembly is provided. The modular connector comprises at least two passages for receiving prongs of an electric plug, recess portions comprising conductive portion, each of the recess portions being in communication with one of the passages and allowing contact of the receivable prongs with the conductive portion and one or more conducting terminal connected to the conductive portion and connectable to a controller.

The modular connector may comprise a status indicator connected to the conducting terminal. The modular connector may comprise a speaker and a microphone. The modular connector may comprise a RFID reader configured to detect a plug having an RFID tag.

In another aspect of the invention, a method for selectively powering an electrical outlet assembly is provided. The method comprises supplying a detection signal to a first conductive portion of the electrical outlet assembly, detecting insertion of one or two blades of an electric plug between the first conductive portion and an electrical connector of the electrical outlet and supplying an operative voltage to the electrical connector when two blades are detected as being inserted in the electrical outlet.

The method may further comprise detecting insertion of the blade of the inserted electric plug over a second conductive portion of the electrical outlet assembly, the detection of the insertion being indicative of the blade being fully inserted.

The detection of the insertion of the blade of the inserted electric plug over the first conductive portion may be indicative of a blade being inserted and the detection of the insertion of the blade of the inserted electric plug over the second conductive portion being indicative of a blade being fully inserted.

The method may further comprise detecting insertion of a first of the blades of the inserted electric plug, detecting insertion of a second of the blades of the inserted electric plug, measuring duration between the insertion of the first blade and the insertion of the second blade and supplying an operative voltage to the electrical connector if the measured duration is below a predetermined duration.

Other and further aspects and advantages of the present invention will be obvious upon an understanding of the illustrative embodiments about to be described or will be indicated in the appended claims, and various advantages not referred to herein will occur to one skilled in the art upon employment of the invention in practice.

### BRIEF DESCRIPTION OF THE DRAWINGS

The above and other aspects, features and advantages of the invention will become more readily apparent from the following description, reference being made to the accompanying drawings in which:

FIG. 1 is perspective view of an embodiment of a modular power outlet assembly in accordance with the principles of the present invention.

FIG. 2 is perspective view of the modular electrical outlet assembly of FIG. 1 shown with an electric plug inserted in one of the modular receptacles and with a USB-C plug inserted in the same modular receptacle.

FIG. 3 is perspective view of the modular electrical outlet assembly of FIG. 1, shown with one of the modular receptacles being removed.

FIG. 4 is a top plan view of the modular power outlet assembly of FIG. 1.

FIG. 5 is a front sectional elevation view of axis A-A of the modular power outlet assembly of FIG. 4.

FIG. 6 is a perspective sectional view of axis A-A of the modular power outlet assembly of FIG. 5.

FIG. 7 is a perspective sectional view of the modular power outlet assembly of FIG. 6 shown with one of the modular receptacles being removed.

FIG. 8 is perspective view of an embodiment of a modular receptacle of a modular electrical outlet assembly in accordance with the principles of the present invention having an embodiment of a child-proof module.

FIG. 9 is a side elevation view of the modular receptacle of FIG. 8.

FIG. 10 is perspective view of an embodiment of a modular receptacle of a modular electrical outlet assembly in accordance with the principles of the present invention having a 2A maximum electrical socket.

FIG. 11 is perspective view of an embodiment of a modular receptacle of a modular electrical outlet assembly in accordance with the principles of the present invention having two USB-A ports.

FIG. 12 is perspective view of an embodiment of a modular receptacle of a modular electrical outlet assembly in accordance with the principles of the present invention having a speaker.

FIG. 13 is side elevation view of another embodiment of a modular receptacle of a modular electrical outlet assembly having another embodiment of a child-proof module.

FIG. 14 is a front sectional elevation view of axis A-A of the modular power outlet assembly of FIG. 4 comprising the modular receptacle of FIG. 13.

FIG. 15 is a perspective sectional view of axis A-A of the modular power outlet assembly of FIG. 4 comprising the modular receptacle of FIG. 13.

FIG. 16 a diagram of embodiments of electric and electronic components of a modular electrical outlet assembly in accordance with the principles of the present invention.

FIG. 17 is a perspective view of a bracket for receiving a modular electric outlet in accordance with the principles of the present invention.

FIG. 18 is a side elevation view of the bracket of FIG. 17.

FIG. 19 is a perspective view of another embodiment of a modular power outlet assembly in accordance with the principles of the present invention.

FIG. 20 is a front plan view of the modular power outlet assembly of FIG. 19.

FIG. 21 is a perspective exploded view of the modular power outlet assembly of FIG. 19.

FIG. 22 is a side sectional elevation view of the modular power outlet assembly of FIG. 19.

FIG. 23 is a perspective sectional view of the modular power outlet assembly of FIG. 19.

FIG. 24 is a perspective view of an embodiment of a removable receptacle of the modular power outlet assembly of FIG. 19.

FIG. 25 is a front elevation view of the removable receptacle of FIG. 24.

FIG. 26 is a right-side elevation view of the removable receptacle of FIG. 24. FIG. 27 is a top plan view of the removable receptacle of FIG. 24.

FIG. 28 is a top perspective view of different embodiments of removable receptacles according to the principles of the present invention.

### DETAILED DESCRIPTION OF THE INVENTION

A novel modular electrical outlet assembly and method of use will be described hereinafter. Although the invention is described in terms of specific illustrative embodiments, it is to be understood that the embodiments described herein are by way of example only and that the scope of the invention is not intended to be limited thereby.

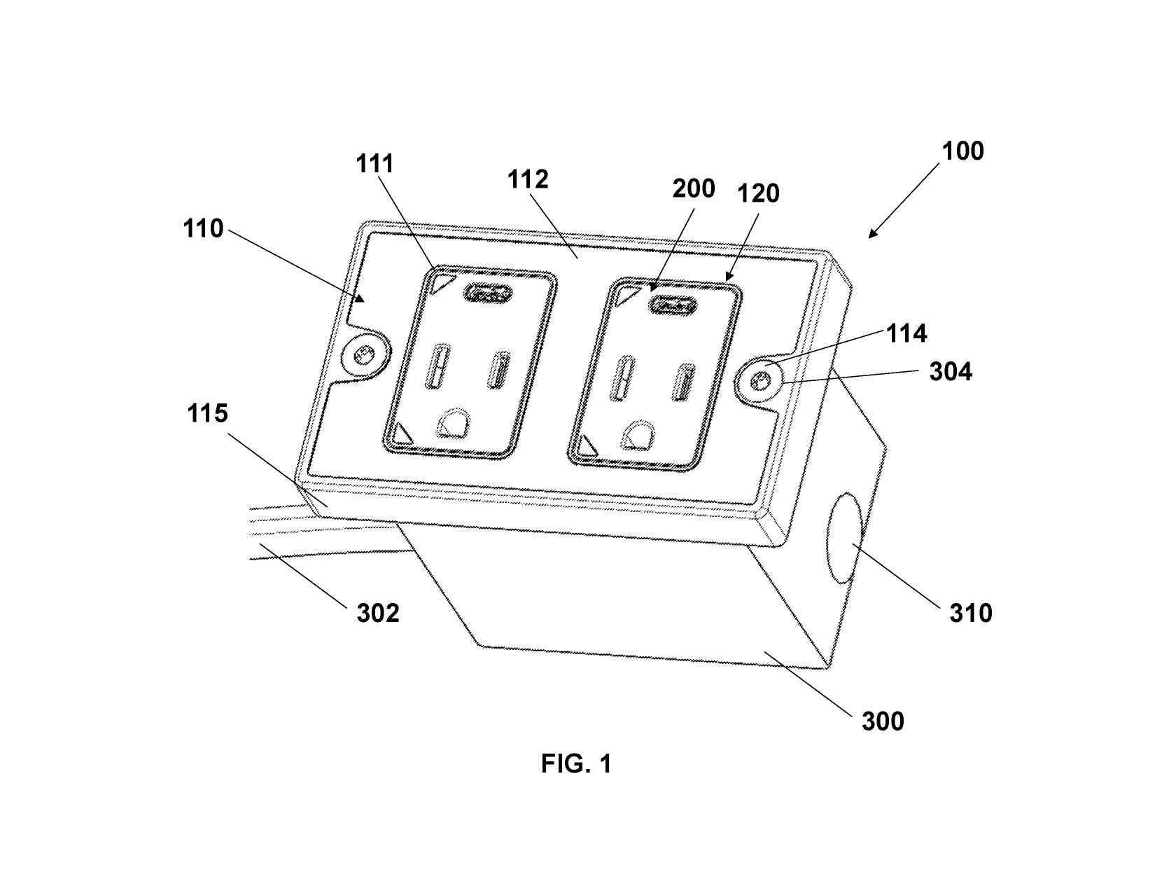

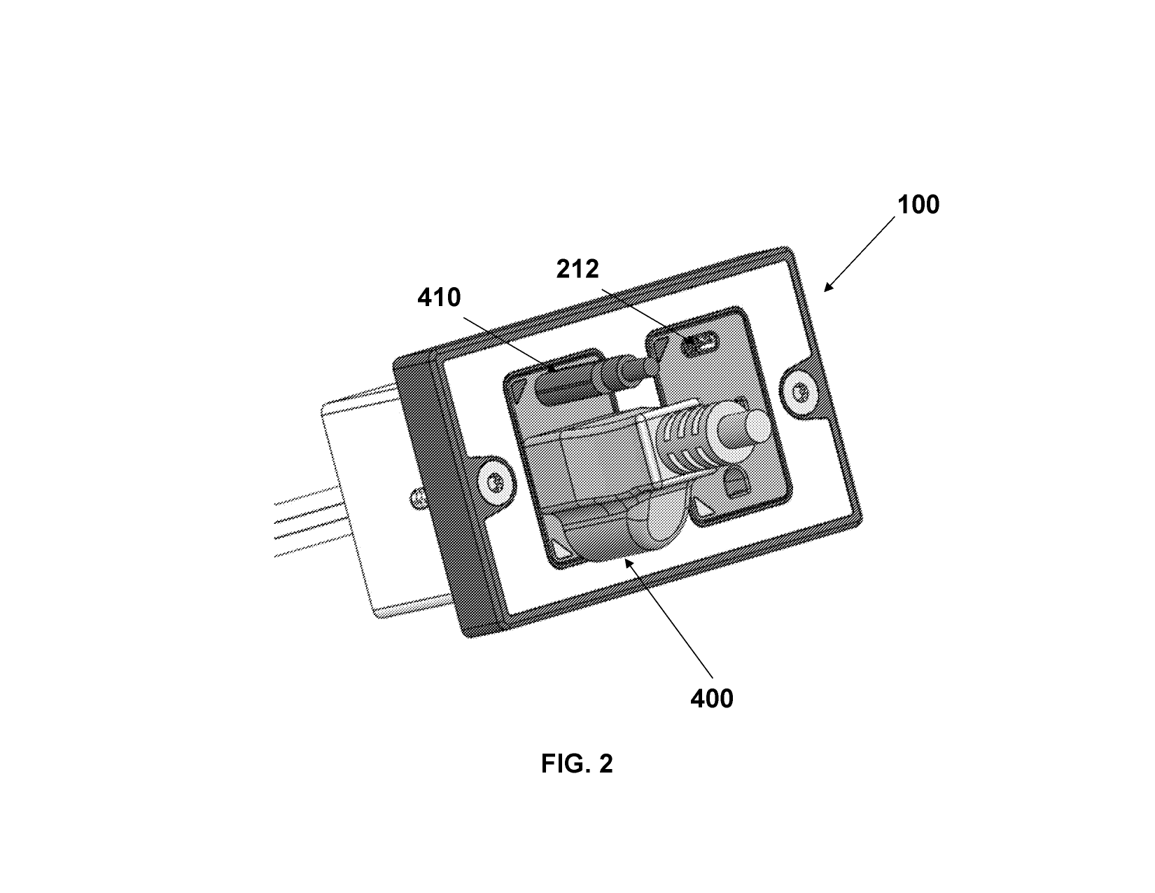

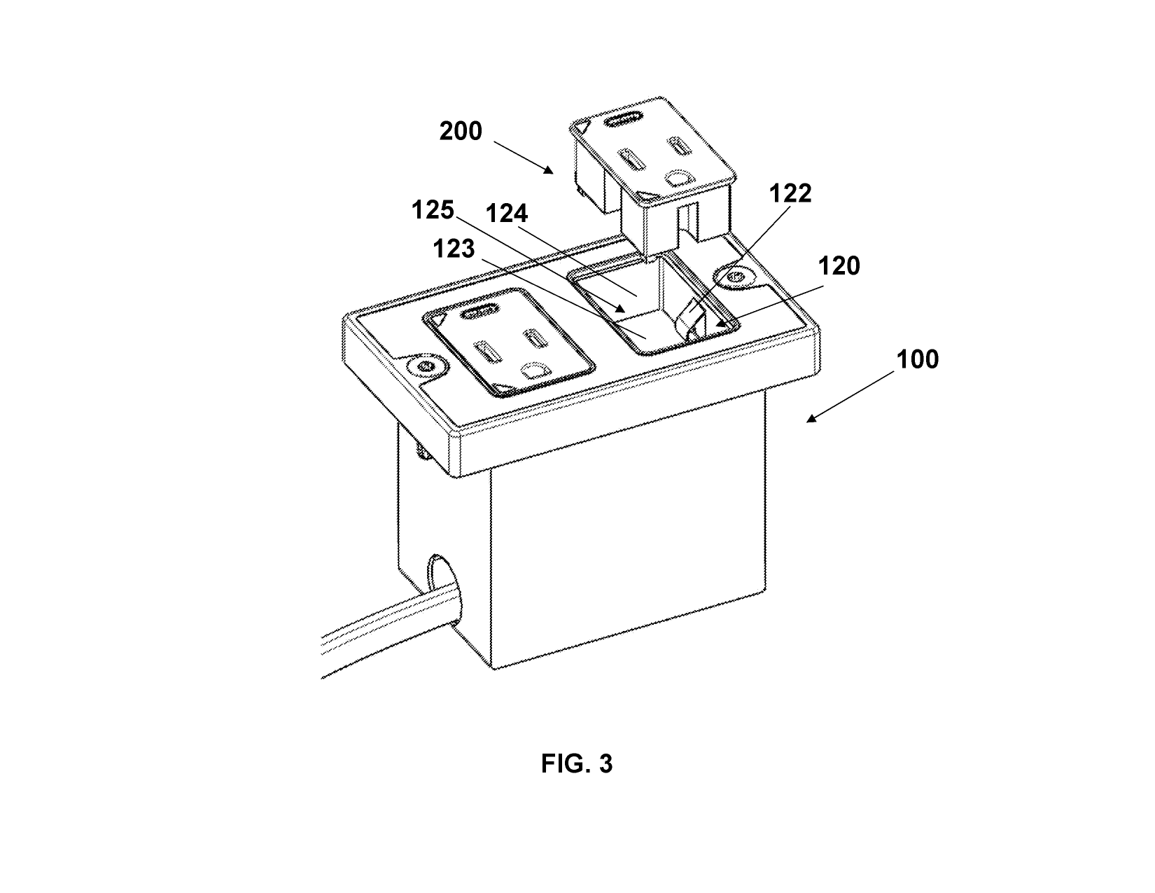

Referring first to FIGS. 1 to 3, an embodiment of a modular electrical outlet 100 is illustrated. The modular electrical outlet 100 is shown installed in an exemplary electrical outlet box 300. The electrical outlet box 300 comprises an aperture 310 allowing passage of an electrical wire 302 to power an electrical outlet to be mounted in the box 300.

The modular electrical outlet 100 comprises a top covering portion 110. The top covering portion 110 comprises a top plate 112 having one or more receptacles apertures 111. The top covering portion 110 further comprises fastening means 114 adapted to mount the top covering portion 110 and/or the modular electrical outlet 100 to the electrical outlet box 300. Understandably, in other embodiments, the electrical outlet box 300 may be replaced with any means or mechanism known in the art to receive an electrical outlet. In some further embodiments, the top plate 112 or top portion 110 may be detachable from the modular electrical outlet 100.

In some embodiments, the top covering portion 110 may have a thickness 115 adapted to receive electronic components, such as but not limited to an antenna, a central processing unit, a PCB with or without a microprocessor, a memory, a RFID reader, a wireless data communication module, such as Wi-Fi, Bluetooth^{TM} or Zigbee, etc. Furthermore, a thicker covering portion 110 may be required when the electrical outlet 100 is installed in outlet box within a wall. As such, the additional volume may allow connecting wires using electrical wire connectors.

In some embodiments, the top covering portion 110 may be made of plastic or any other rigid non-conductive material. The upper portion of the top covering portion 110 may also include holes or passages adapted to receive fasteners 304, such as but not limited to screws. The fasteners 304 generally aims at fixing the modular electrical outlet 100 to the electrical outlet box 300 or to any surface.

In further embodiments, the top portion 110 may be a thin faceplate, such as when installed in transportation vehicles such as trains or bused.

The modular electrical outlet 100 further comprises one or more receptacle receiving portions 120. The receiving portion 120 comprises a recess 125 adapted to receive and detachably attach a modular receptacle 200. The recess 125 is generally formed by a bottom surface 123 and wall 124. The shape of the recess 125 preferably allows a tight of the modular receptacle 200 when inserted. In some embodiments, the recess 125 may be shaped to allow insertion of a receptacle extraction tool allowing extraction or pulling of the receptacle 200 from the receiving portion 120.

The receiving portion 120 further comprises resilient electric connectors 122 to connect with a contact or blade 402 of an electrical plug 400. The resilient electric connectors 122 may be made of any conductive material, such as copper. The resilient electric connectors are typically located parallel to walls 124 of the receiving portion. In the illustrated embodiment, the neutral and live connectors 122 are facing one another and a ground connector 123 is located on a perpendicular wall.

In some embodiments, the modular receptacle 200 may be adapted to allow connection of other types of plugs, such as but not limited to a charging or data communication port. In the illustrated embodiment, a USB-C plug 410 is connected to a female connector 212 of the modular receptacle 200. Other connectors may include USB- A connector, Thunderbolt^{TM} connector, HDMI^{TM} connector, DisplayPort connector or any known or to be adopted port.

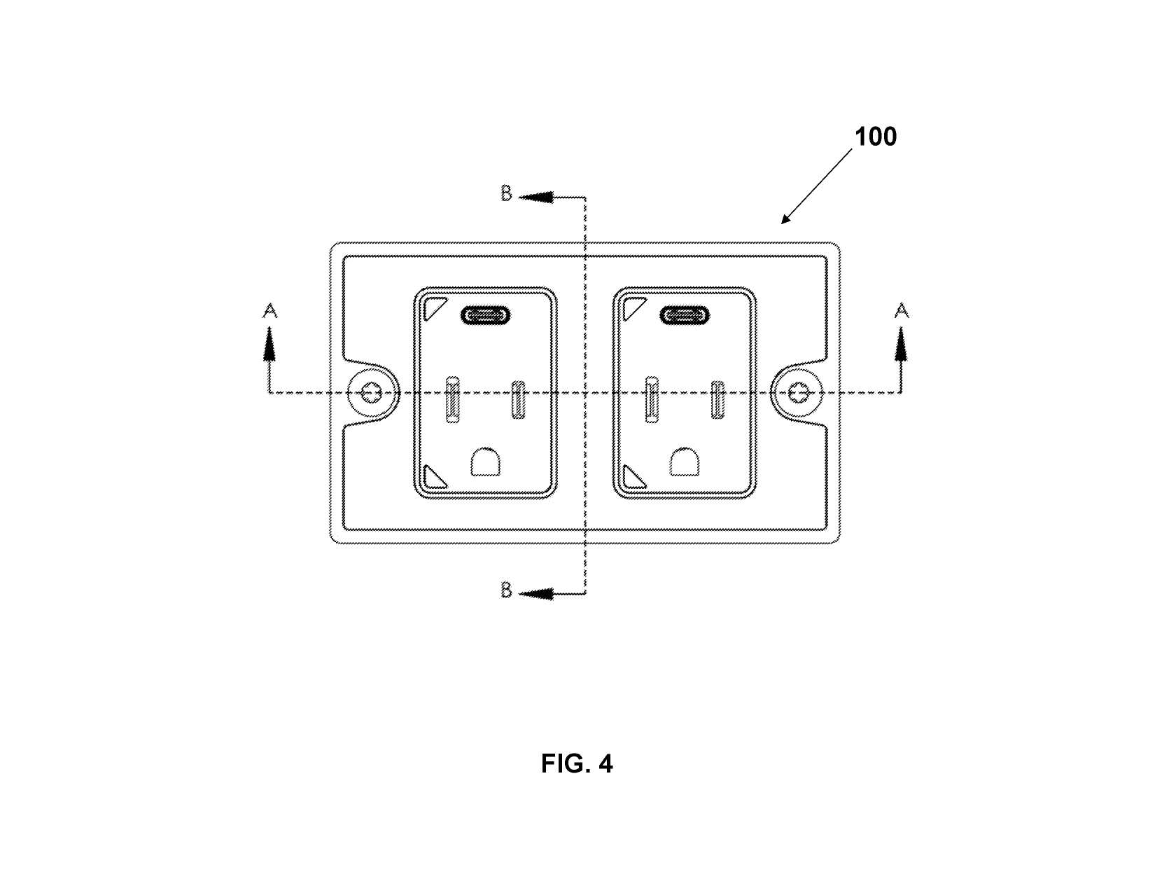

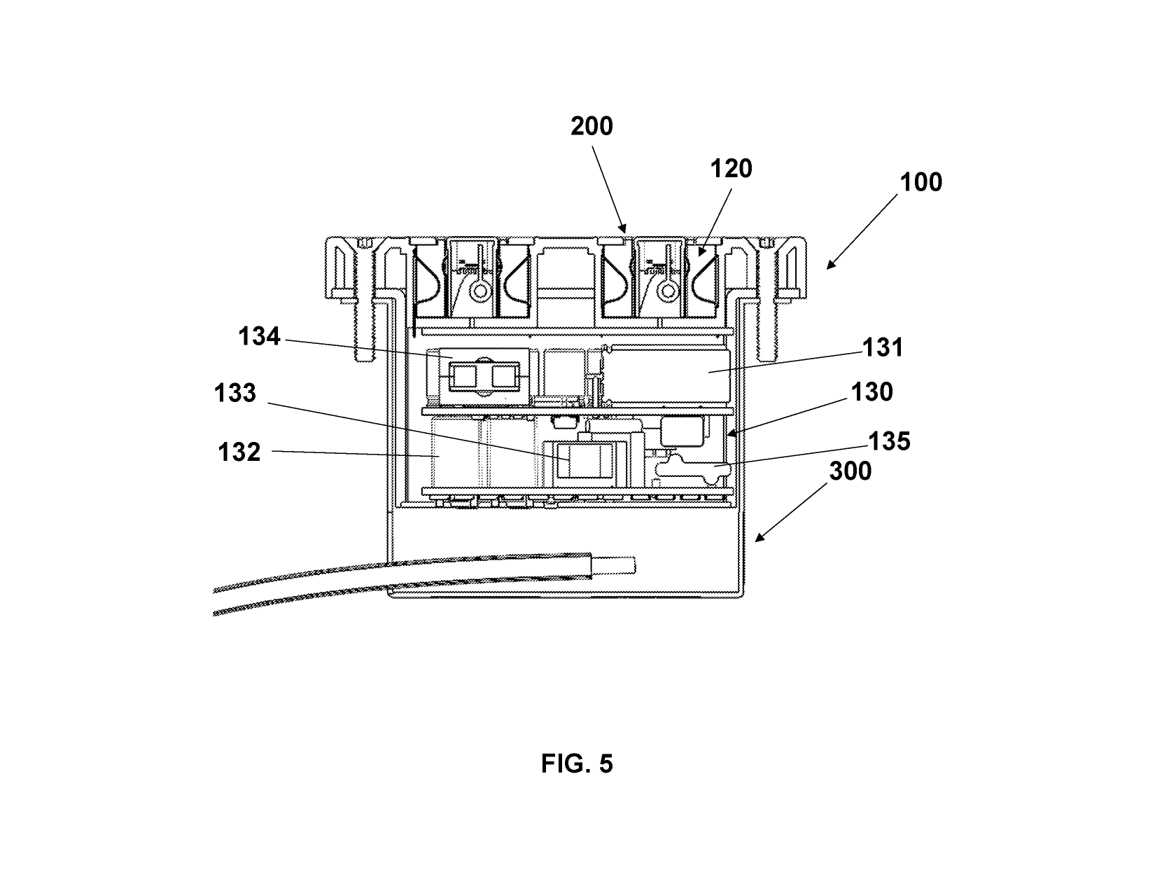

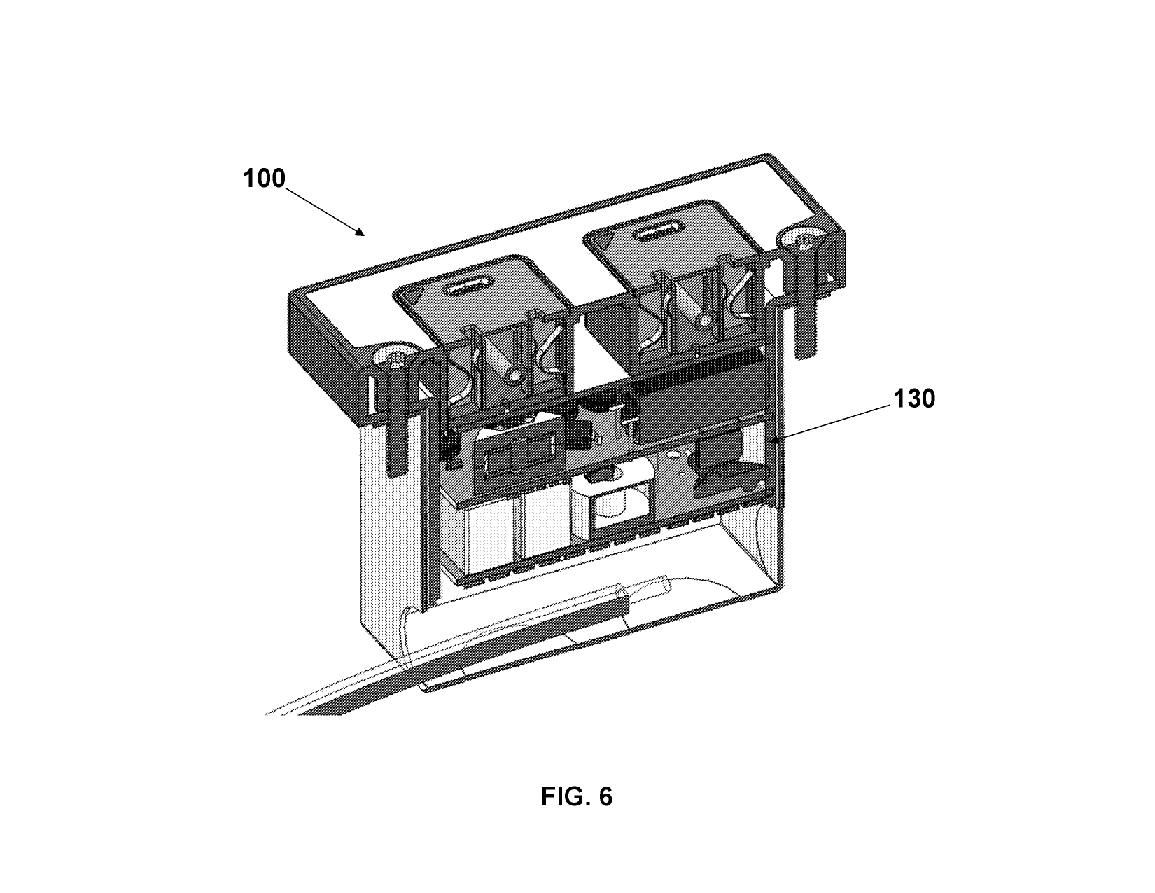

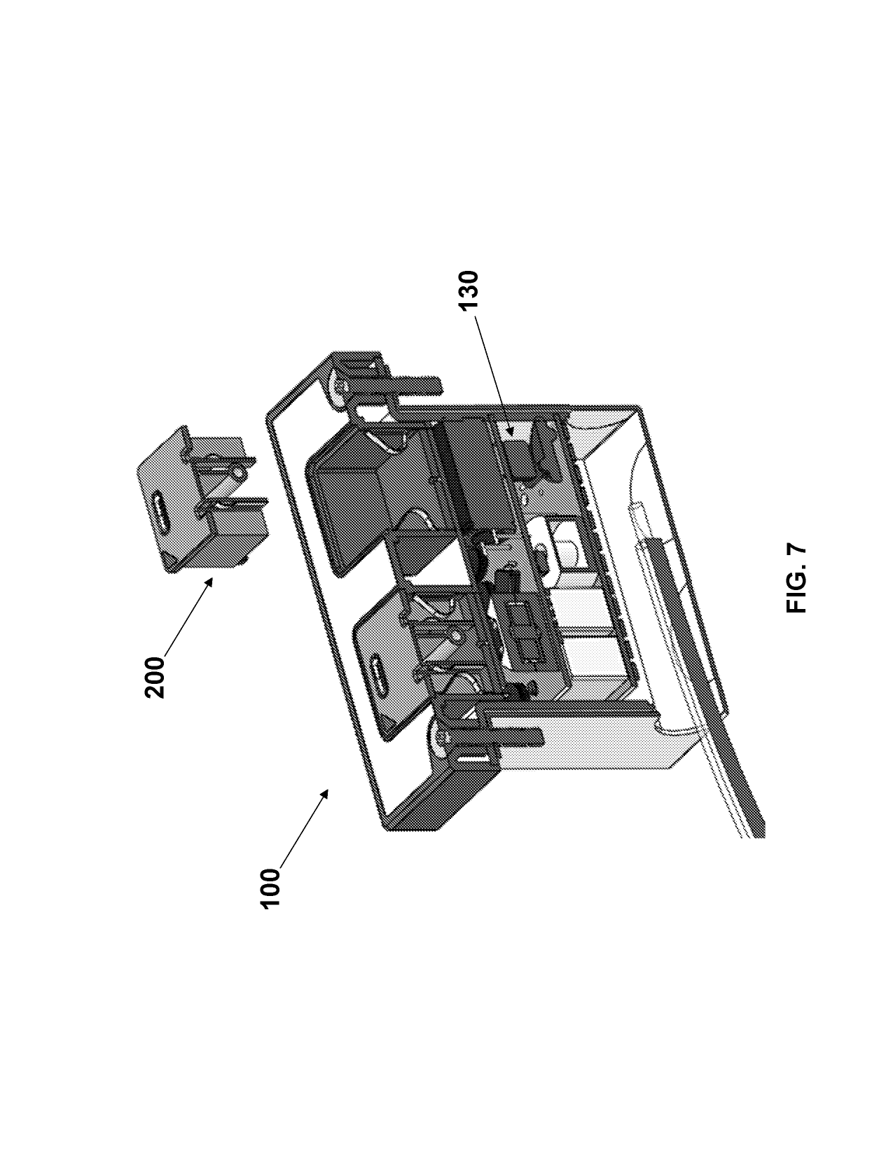

Referring now to FIGS. 4-7, the embodiment of a modular electrical outlet 100 is illustrated, showing inner components. Referring to FIG. 5, the modular electrical outlet 100 comprises a housing or body 130 attached or unitary to the top covering portion 110. The body 130 is adapted to receive electronic components ensuring electrical protection of the modular electrical outlet 100.

The electronic components may be positioned within the body 130. The electronic components may comprise but are not limited to electronic components described in the US Provisional patent application no. 63/463,278, filed on May 1, 2023.

When used in a public environment, the modular electrical outlet 100 may comprise a power limiting circuit to consider voluntary actions of overloading and short-circuiting in the sockets 230 and/or 212.

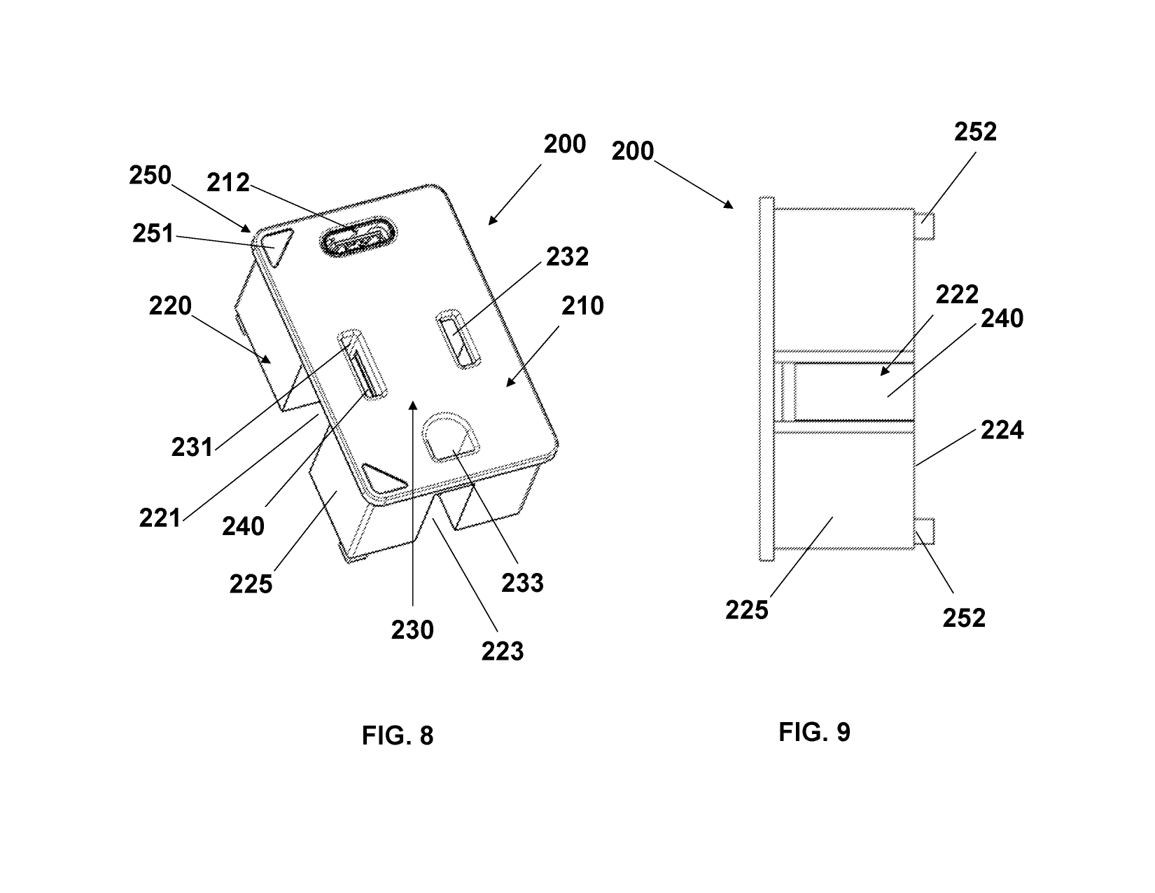

Referring now to FIGS. 8 and 9, an embodiment of a modular electrical receptacle 200 is illustrated. The modular electrical receptacle 200 comprises a top portion 210 and a body portion 220. The top portion 210 may comprise a charging port 212, as discussed above, and an electrical plug receptacle 230, such as but not limited to a standard 120V receptacle, 220V receptacle or any other standard electrical plug receptacle. In the illustrated embodiment, the electrical plug receptacle 230 comprises a first 231 and second 232 apertures for receiving a live and neutral contacts or blades 402 of an electrical plug 400. The electrical plug receptacle 230 may further comprise a third aperture 233 for receiving a ground contact of an electrical plug 400. Each of the apertures 231, 232, 233 are connected to passages 221, 222, 223, respectively, which are formed in the body portion. Each of the passages 221, 222, 223 allows a contact of the plug to be inserted and to contact with the electric connectors 122 and/or child-proof conducting plates 240 of the receptacle 200.

The passages 221, 222, 223 may have any shape allowing passage of the contacts and connection with the resilient electric connectors 122 of the receiving portion 120. As such, when inserted, the contacts of the plug 400 pass through the apertures 231, 232, 233 and are pushed in the passages 221, 222 and 223 until the plug 400 is stopped by the top plate 112. The resilient electric connectors 122 then push against the inserted contacts of the plug 400. In the illustrated embodiment, the passages 231, 232, 233 are recesses within side walls 225 of the receptacle 200.

In the illustrated embodiment, the passages 221, 222 and 223 are shape as parallelograms. Understandably, any other shapes of the passages 221, 222 and 223 may be used within the scope of the present invention.

As discussed above, the outer shape of the receptacles 200 preferably allows a tight fit when inserted in the receiving portion 120. In other embodiments, any fastening member or means may be used to mount or attach the modular receptacle 200 to the receiving portion 200 or to the top portion 110.

When the receptacles 200 are failing, due to vandalism act or to electrical failure, one may pull the receptacle 200 from the receiving portion 210. When removed, the receptacle 200 is not powered, thus it is safe for one to manipulate within risking any electrical shock. As an example, one may use any tool or hands to remove gum which would have been inserted in any of the apertures 231, 232, 233 and/or in the passages 221, 222 and 223. When the maintenance is completed, if the modular receptacle 200 is still functional, the said modular receptacle 200 may be reinserted in the receiving portion 210. The apertures 231, 232, 233 and/or in the passages 221, 222 and 223 generally aim at providing easy cleaning, especially for electrical outlets in public places prone to vandalism. Having passages 221, 222 and 223 extending from one end to the other of an easily removable connector block 200 makes it easy, for example, to push a piece of detritus inserted in the socket to be exited on the other side.

The modular receptacle 200 generally allow flexible and modular configuration of the electrical outlet 100. In some embodiments, an electrical outlet 100 may comprise a single block 200 while other embodiments may comprise a two or more blocks 200. As such, the outlet assembly 100 may comprise a first block comprising two USB ports and a second block 200 comprising a 120V outlet. The modular receptacles 200 may be interchanged at any time during the operating life of the electrical outlet 100.

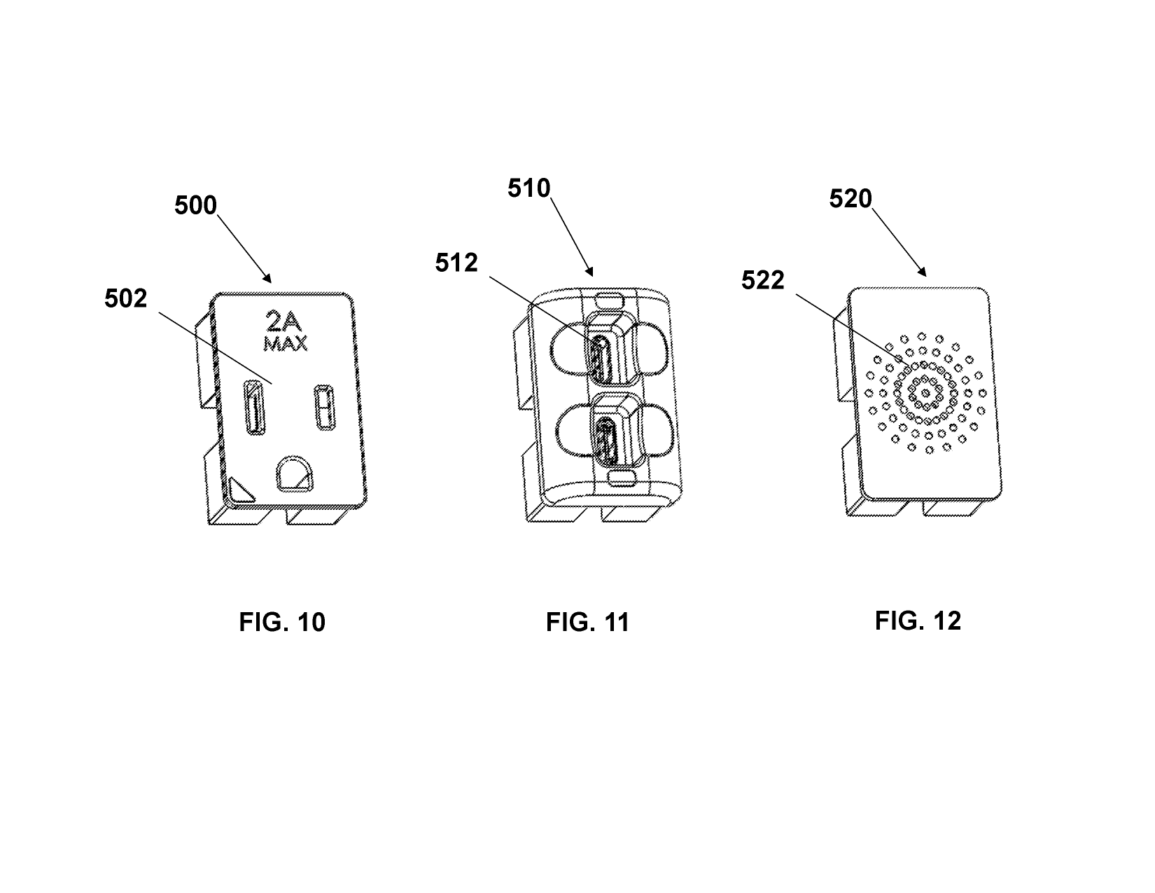

Referring now to FIGS. 10 to 12, different exemplary modular receptacles or blocks 500, 510 and 520 are illustrated. Referring to FIG. 10, a modular receptacle 500 comprising a single high voltage socket 502 is illustrated. In such embodiment, the modular receptacle 500 may only receive electrical plug connected to devices requiring low current, such as a maximum of 2A. Understandably, any other limit of current may be used within the scope of the present invention. Referring to FIG. 11, a modular receptacle 510 comprising two charging ports 512 is illustrated. In such embodiment, the powered charging ports 512 are USB sockets adapted to connect to device powered by current provided by such ports. Understandably, the charging ports 512 may be embodied as any types of known USB sockets or future USB sockets, such as but not limited USB-A or USB-C sockets.

Referring to FIG. 12, a modular receptacle 520 comprising a speaker or sound emitting device 522 is illustrated. In such embodiment, the speaker 522 is powered by the electric connectors 122 of the top portion 120 of the outlet. Understandably, and as discussed below, many other types of modular receptacles having other functions are within the scope of the present invention.

In some embodiments, the modular electrical outlet 100 may comprise a child-proof protection associated with each of the high voltage, such as 120Vac, modular electrical receptacle 230. In such embodiment, the modular electrical outlet 100 comprise an electronic circuit configured to apply power to the modular electrical outlet only when at least two high voltage blades 402 of an electrical plug 400 are inserted in apertures 231 and 232 within a certain time frame. As such, a user inserting a metallic piece into the live apertures 231 or 232 shall not be exposed to electrical shock.

In embodiments having a child-proof protection, the modular electrical outlet 100 may comprise an inserted plug detector circuit. The detector circuit typically comprises an electrical transformer connected to a secondary winding connected in series with the four isolated half-sockets or electrical contacts 121 and 122 within the receiving portion 120. The detector circuit may further comprise a capacitive/resistive load connected between the contacts 121 and 122 and conduction portions 221 and 222 inside the modular electrical receptacle 200. In use, when a high voltage electrical plug 400 (i.e. 120Vac) is inserted in the receptacle 200, each of the two conductive blades 402 of the plug 400 connects the two half-contacts 121/122 with contacts 221/222, thus closing the circuit allowing the secondary winding of the transformer to feed the capacitive/resistive load. The plug insertion event can be detected on the primary side of the transformer by measuring the change of its impedance (mutual inductance change). Then, only when both blades 402 of a high voltage plug 400 are inserted, the internal relay is activated powering the receptacle outlet contacts 121/122 with the high voltage source. Such feature may further allow reducing contacts wearing due to sparks.

In some embodiments, the modular receptacle 200 may comprise child-proof conducting plates 240 adapted to contact with the live or neutral contacts of an inserted electrical plug 400. As such, the said plates 240 are powered by an isolated low voltage circuit, such as a 6V circuit. The low voltage circuit ensure that a user may not receive an electrical shock. When the 6V isolated circuit is closed, by the insertion of the contacts of the plug 400, a controller detects the change in impedance and power the high voltage or operative voltage (such as 120V) circuit through the connectors 122 only when the insertion sequence timing is followed. As such, the modular electrical outlet 100 may comprise an internal impedance combination circuit configured for the driving circuit to identify if only one blade or both blades 402 are connected to the electric connectors 122. The impedance combination makes three levels of impedance (no blade connected, one blade connected, two blades connected). The driving circuit may further have a timing stage which validates that at least two blades 402 are connected within a short timing before allowing the relay to apply power. In some embodiments, the short timing duration is generally preset to a timing that is normally observed when inserting a high voltage plug (i.e. 120Vac). The detection of the levels of impedance generally prevents a user from inserting two objects in the outlet and to activate power. As such, any child (or older user) tampering with the electrical outlet without an electrical plug inserted is safe from receiving an electrical shock as the electrical outlet 100 is powered by a low-voltage when not in use.

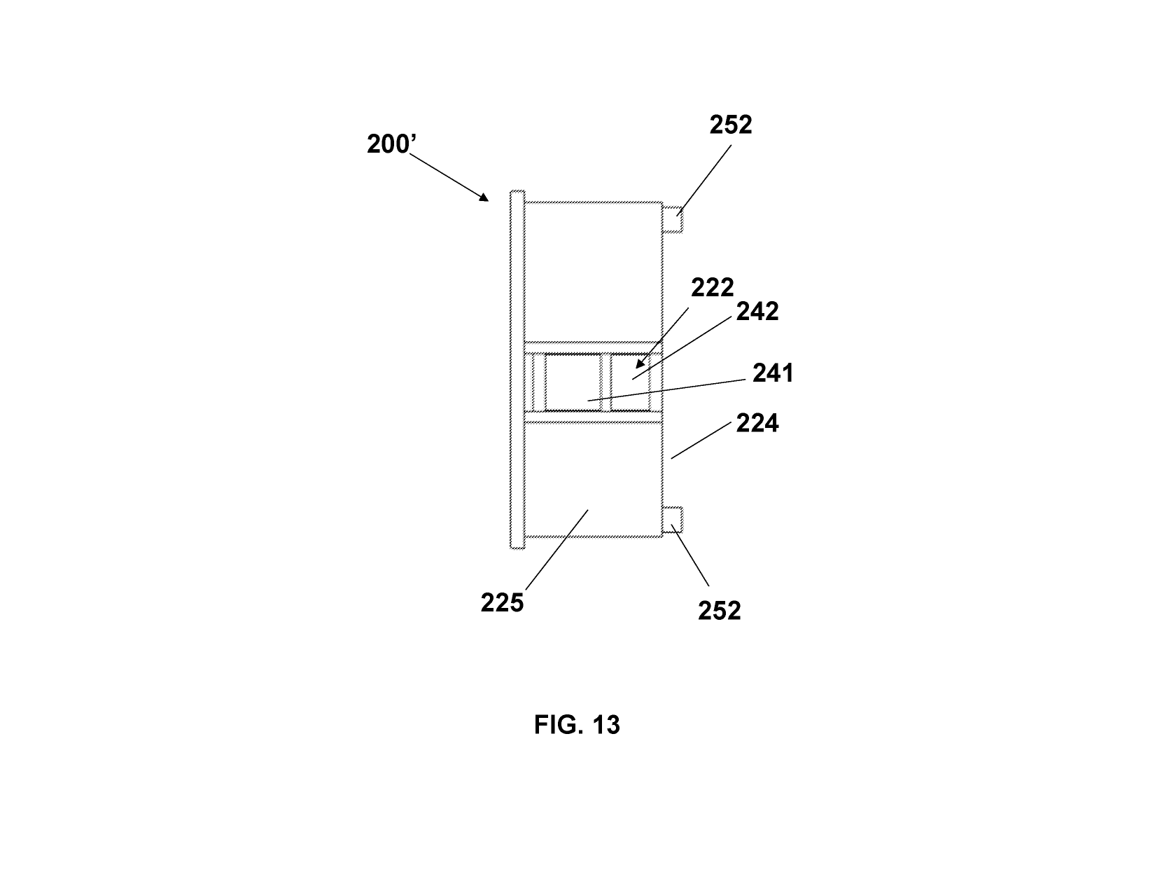

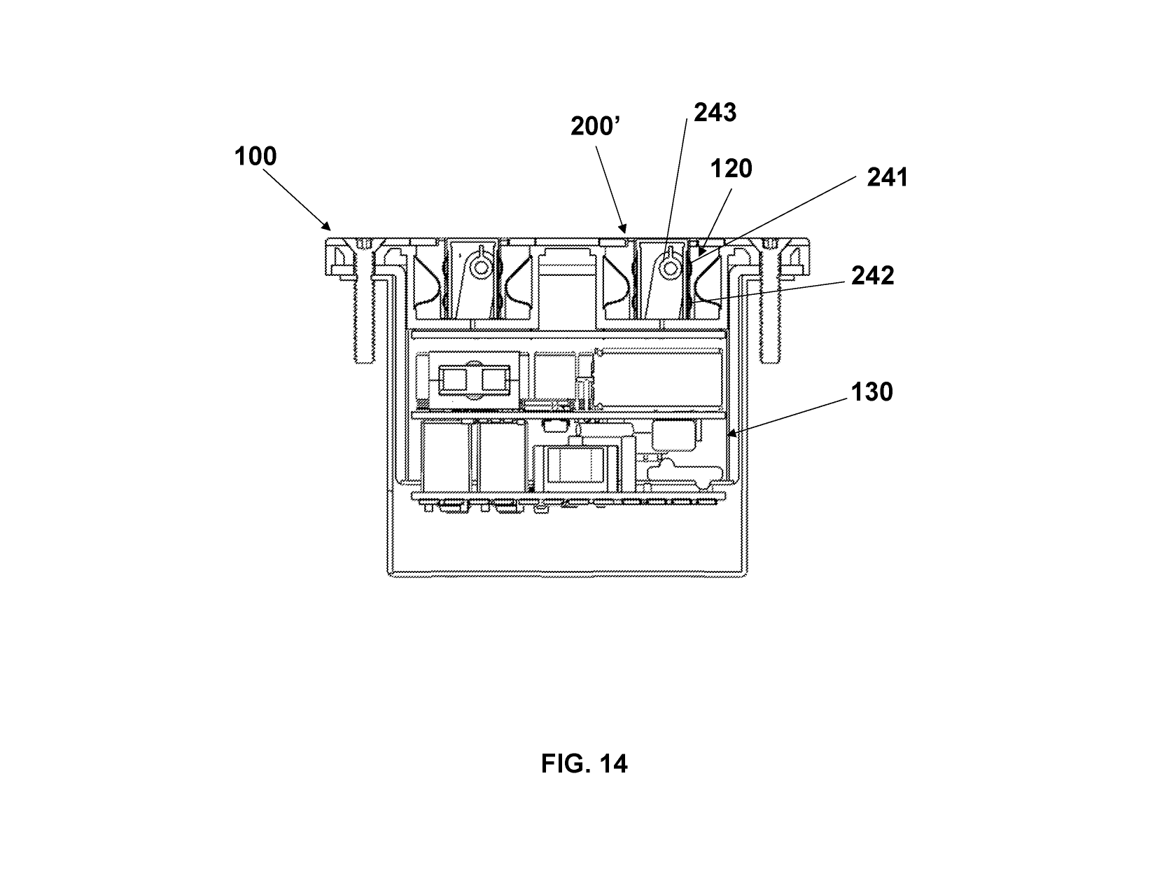

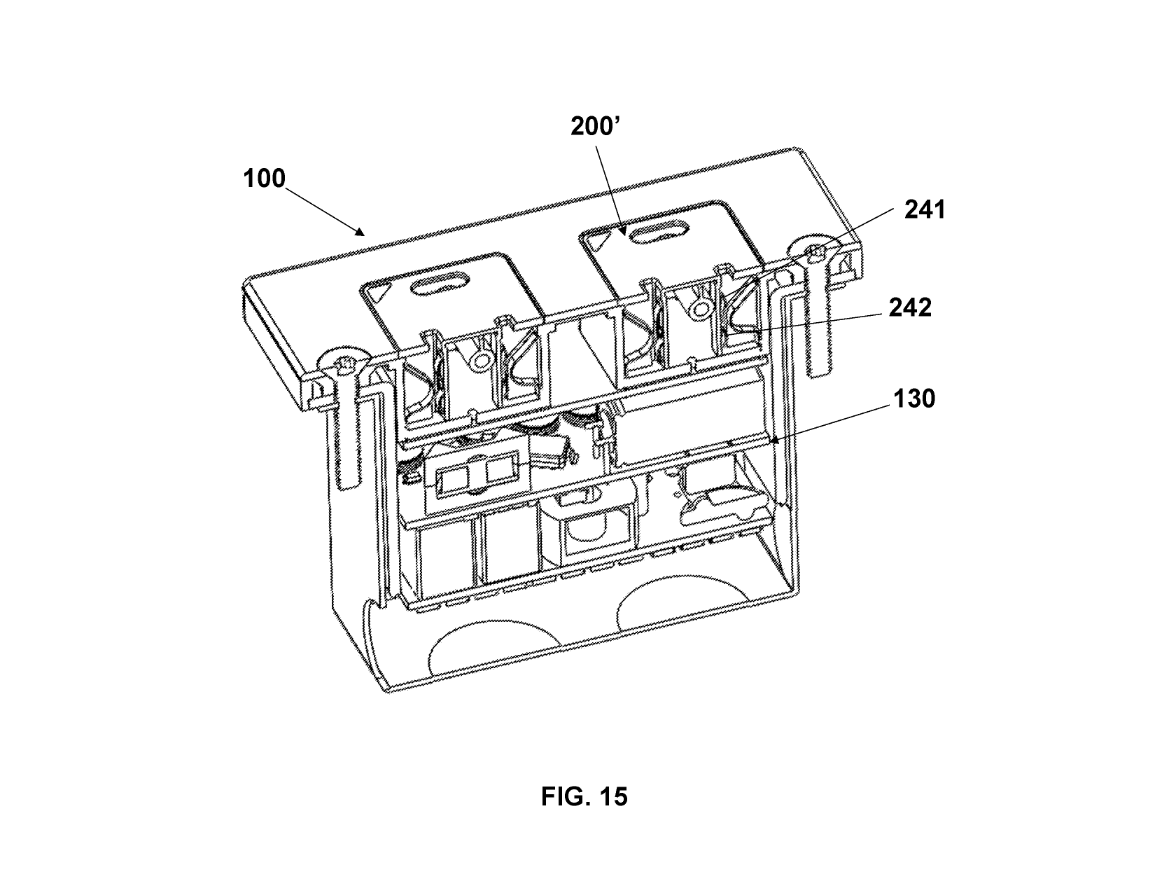

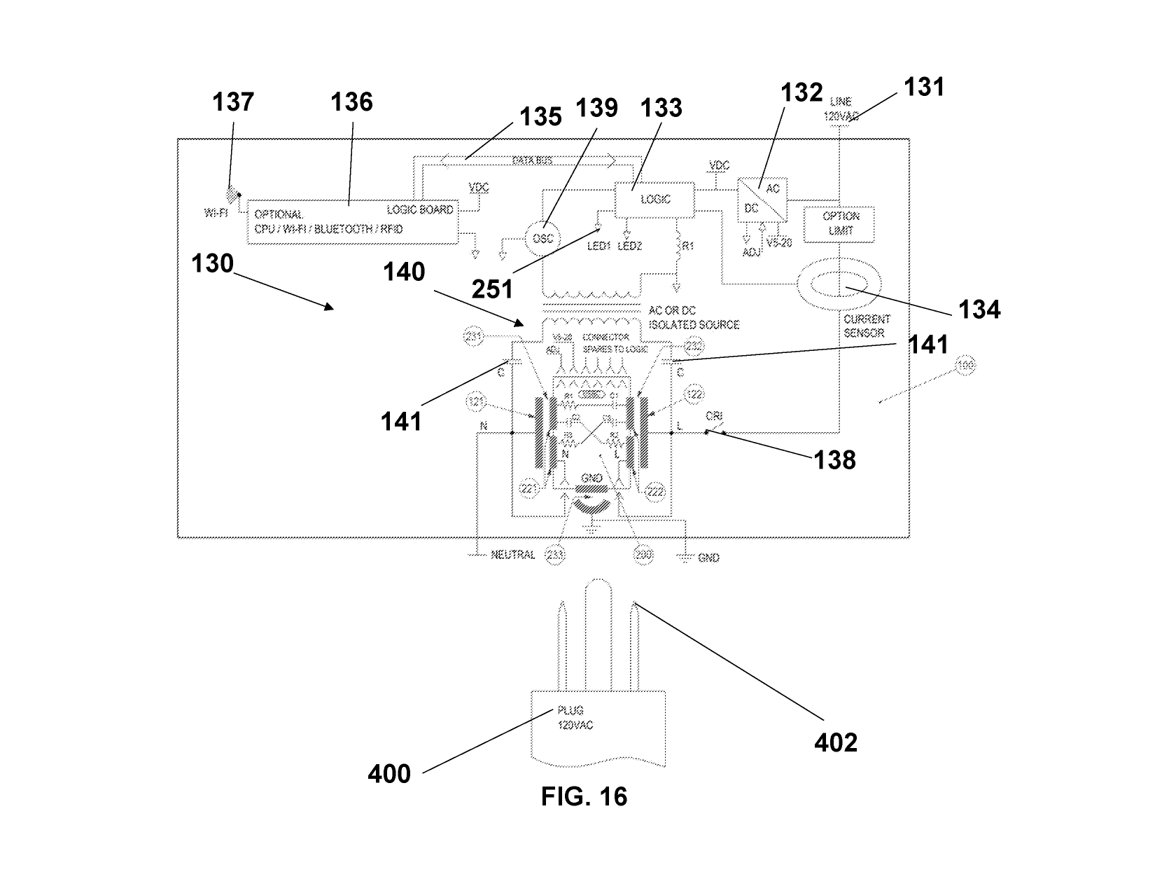

Referring now to FIG. 13, another embodiment of child-proof modular receptacle 200' is illustrated. In such embodiment, the receptacle 200' comprises two conducting plates 241 and 242. As such, when the blades 402 contact with the upper conducting plate 241, the controller 136 detects a first change in impedance or that the impedance reaches a predetermined level. When the blades 402 are further pushed in to the passages 221, 222 and/or 223, the blades 402 contact the lower conducting plate 242. As the controller 136 detects a second change in impedance or that the impedance reaches a predetermined level on the second conducting plate 242, it is assumed that that plug is fully inserted within the receptacle 200'. At this moment, the controller 136 closes the relay 138 (see FIG. 16) and powers the outlet 100 with the high voltage (i.e. 120V) as the outlet may be safely used. Referring now to FIGS. 14 and 15, the receptacle 200' is shown inserted in the receiving portion 120 of the outlet 100.

In yet other embodiments, the modular receptacle 200, 200' may comprise a status display module 250 which is configured to display the status of each of the connectors 212 or 230 of the receptacle 200, 200' or 500. In the illustrated embodiment, the status display module 250 comprises a LED indicator 251 for each of the connectors 212 or 230. Each of the LED indicator 251 is connected to conducting terminal 252 located on a bottom portion 224 of the body 220 of the receptacle 200, 200' or 500. The conducting terminal 252 are insertable in compatible port (not shown) present in the receiving portion 120 and in data communication with the controller. In the illustrated embodiment, the LED indicator 251 may use different colors for different status, such as but not limited to blue being an operative status, red being a defective status, such as a power overload or unpowered event, blinking red being a ground fault detected and unpowered, etc. Such LED indicators 251 may generally indicate powering status of the electrical outlet 100 or status of the USB-C socket 212. The lower indicator may be a green light when a high voltage is available or be a red light when an overcharge condition is present.

In the illustrated embodiment of FIGS. 1-9, each connector block 200 comprises a standard electrical socket 230 and a USB-C socket 212 located above the electrical socket to allow both an electrical plug and a USB cord to be connected at the same time, if necessary. In such embodiment, the modular electrical outlet 200 is powered by a high voltage (i.e. 120V) but, as discussed above, the electronic components only allows a low- voltage circuit when the connectors blocks 200 are not in used and allow a 5V circuit to power the charging port 212. As such, the modular electrical outlet 200 comprise known in the art power converters to convert high voltage circuit to lower voltage circuits. In the illustrated embodiment, the power converter may output either 5V DC or 20V DC to power the charging socket port 212, such as USB-C port, in a power delivery mode. In some embodiments, the connector block 200 may include robust or industrial electrical power connector allowing a very high number of cycles for intensive duty in public areas.

In yet other embodiments, the removable receptacles may be embodied as modular block providing a plurality of functions or features. As such, in some embodiments, a modular block 520 may comprise a speaker 522, to be used, as examples, for playing music, triggerable ambient sequential sound effects in several rooms of a building, alerts, vocal interface such as but not limited Alexa^{TM}, Google assistant^{TM}, SiriTM, CortanaTM, etc., as an intercom or any other sound uses. In other embodiments, the modular block may further comprise a microphone, a light, a data communication module, such as WIFI, Bluetooth^{TM} or others, a presence detector module or any other smart feature integrable into the modular block 200. The modular block 200 may further comprise remotely programmable logic functions, multi-color programmable LED floor lighting with activated based on a schedule or outdoor lighting dependant on geographical location, energy storage capacitor in case of input power outage, phone call module using voice detection and recognition, ChatGPT^{TM} assistance, baby/seniors requiring home monitoring assistance/surveillance or any other audio pickup purposes, RMS Power consumption measurement for statistic reporting/alert, energy management/optimization, gas/heat/smoke detectors for alarm purposes, push button for manual human intervention as GFI reset/test or as an alarm button for assistance or urgencies (see below).

As such, each of the block 200 may become part of network of smart objects and may be in communication with a central server to provide interconnected features, such as but not limited to playing sound through a plurality of blocks 200, turning on or off light blocks at certain time, creating an intercom system, etc.

In other embodiments, the electrical outlet 200 or the top portion 110 may include a built-in RFID reader allowing identification of high voltage electrical devices, such as 120V power devices. Each of the plug 400 to be inserted shall comprise an RFID chip comprising an identification. As such, when connected, the RFID reader detects the RFID chip and the identification. The identification is fetched in a data source comprising the identifications and the associated electrical apparatus or device. Understandably, the data source may be remote to the electrical outlet 200, such as on a remote server accessible through a data network. As such, and as an example only, the system may be configured to log the consumption of each of the device comprising an RFID chip and thus provide a detailed consumption graph or log sheet. It would also be possible to know the number of connections and which devices are connected for each outlet in a building. This would raise awareness for consumption and create automation routines to better manage consumption and costs. In some embodiment, the RFID chip would be inserted in a thin member having apertures fitting the configuration of the plug 400, 410. When positioned on the plug 400, 410, the RFID chip is positioned in between the plug 400, 410 and connection port 230 or 212.

In further embodiments, a remote current sensor (with or without contact) comprising a Wi-Fi communication module and predefined ID may be installed on devices or apparatus (i.e. 120Vac or 240Vac). Each current sensor may be powered by a LI-ion battery (token format) or by solar mean or induction/capacitor. As such, it would be possible to make a layout of the house/building and log the consumption of all identified devices at the different outlets.

In some embodiments, the modular electrical outlet 200may comprise a built-in breaker or any Ground Fault Interrupter (GFI) to further ensure child-proofing on the modular power outlet assembly 200. By way of example, a person inserting his or her fingers or a metal object into the socket will trip the circuit breaker connected to the connector block, preserving the integrity of entire assembly requiring only replacement of the damaged connector block.

Referring to FIG. 16, an embodiment of an electric circuit 130 of the electrical outlet 100 is illustrated. The electric circuit 130 is powered by a high voltage line (i.e. 120Vac). The circuit 130 comprises AC/DC convertor 132 powering a logic module 133 adapted to control LED indicators 251 and in signal communication with an optional limit current sensor 134. The logic module 133 may be further configured to power the isolated low voltage circuit 140 adapted to provide child-proof protection system. The logic module 133 is connected to a controller 136 through a communication link 135, such as a data bus. The controller 136 may comprise a central processing unit (CPU), a WI-FI controller, a Bluetooth^{TM} controller and/or a RFID reader. The controller 136 may further comprise a WI-FI antenna 137. Understandably, in other embodiments, the controller 136 and the logic module 133 may be integrated in a single controller or logic module.

The circuit may further comprise an oscillator 139 and capacitors 141. The oscillator 139 is configured to provide a current at a predetermined frequency. The circuit 140 uses the reactance of the capacitors 141, C1, C2 and C3 to allow operations with an operative voltage and a detection voltage. As such, the frequency of the operative voltage is different of the detection voltage, as such, when the operative voltage is supplied, the capacitors 141, C1, C2 and C3 block passage of the current and protect the resistances R1, R2 and R3 and the control circuit. Understandably, any other known method to allow use of different voltages in a circuit are within the scope of the present invention.

The circuit 140 is further configured to measure variation of the impedances or tension on the circuit as described below. Understandably, any other method known in the art to measure different tensions may be used with the scope of the present invention.

As illustrated at FIG. 16, in use, a low voltage or detection signal powers the outlet 200. As such, when a blade 402 of a plug 400 is inserted in the outlet 200, the conduction portion 222/232 is connected to the electric connector 122 and the conductive portion 221/231 is connected to the electric connector 121. A detection circuit is formed through the pairs of resistances and capacitors R1-C1, R2-C2 and/or R3-C3.

As such, in such embodiment the assembly 100 may detect at least three statuses: one blade 402 being inserted, no blade being inserted or two blades being inserted. As such, if no blade is inserted, the pairs R1-C1, R2-C2 and R3-C3 are connected in series thus creating a high impedance or a higher tension or voltage and forming a first level of impedance. If a short circuit if formed on contacts 222, such as by inserting a blade, impedance is only formed on R3 and C3, thus reducing the tension on circuit 140 and forming a second level of impedance. If a short circuit if formed on contacts 221, by inserting another blade, impedance is only formed on R2 and C2, thus reducing the tension on circuit 140 and forming the same level of impedance as the second level of impedance. The tension of R2-C2 or R3-C3 is lower than the tension of R1-C1, R2-C2 and R3-C3 in series. If a short circuit if formed on both contacts 221 and 222, by inserting a blade in each, R1-C1 become connected in parallel with R2- C2 and in parallel with R3-C3, thus minimizing the impedance or tension and forming a third level of impedance. The third level of impedance is lower than the first two levels. As such, a circuit for detecting the tension (i.e. comparator with reference tensions) may be used to identify the status of the outlet 200.

As such, in some embodiment, when two are detected to be inserted within the outlet 100, the relay 138 is closed to power the circuit with a high voltage or operative voltage. If any of the blades are detected to be removed from the outlet 100, the relay 138 is open to cut the operative voltage.

In yet other embodiments, a sequence of different statuses may be detected by the controller 136 or logic module 133 to validate that a plug 400 is inserted in the outlet 100, instead of any other conductive element used to tamper with the outlet 100. As such, in an exemplary sequence, the controller 136 may identify that a second blade 402 is inserted within a predetermined duration from insertion of a first blade 402. As such, when the predetermine valid sequence of statuses is detected, the relay 138 is closed to power the circuit with a high voltage or operative voltage. If the predetermine valid sequence is not detected, the relay 138 is maintained open.

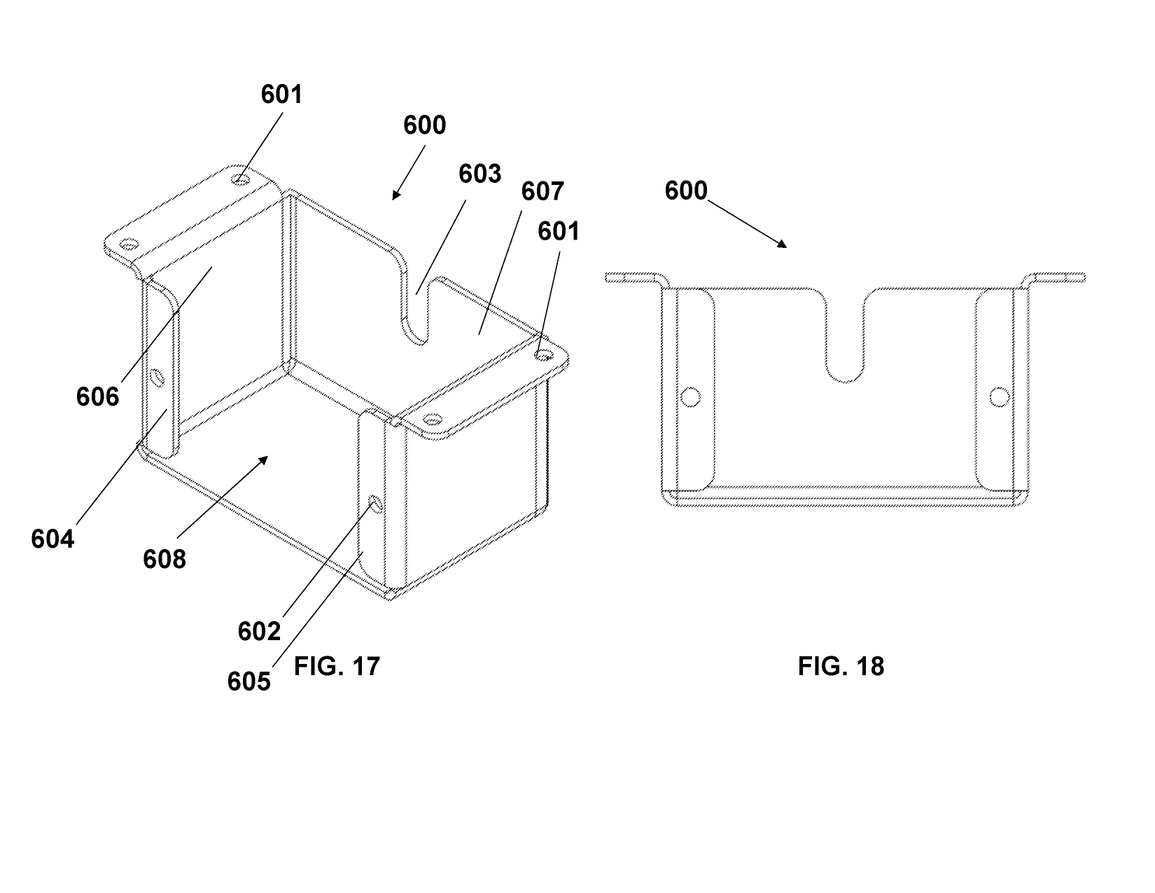

Referring now to FIGS. 17 and 18, a bracket 600 for receiving a modular outlet 100 and attaching the same to a surface, such as a bench or table is illustrated. The bracket 600 comprises upper apertures or passages 601 for allowing fasteners to mount the bracket to a surface, such as a bench, a table or a seat in a transportation, such as a bus or train. The bracket 600 further comprises a recess 603 to allow passage of wires or cables powering the outlet 100. The bracket 600 further comprises side wall 606 and a back wall 607. The front wall is made of two protuberances 604 and 605 extending from the side wall 606. The bracket 600 further comprise side apertures 602 on the extensions or protuberances 604 and 605 allowing passage of fasteners to mount the bracket to a vertical surface. The aperture 608 between the extensions 604 and 605 allows the insertion of the electrical outlet 100. Once inserted, the covering portion 120 protrudes from the aperture 608. As such, the bracket 600 maintains the integrity of the outlet 100 and holds the said outlet 100 in a position accessible for a user when mounted under a seat or under any other object. The bracket 600 is made of rigid material, typically of bent metal.

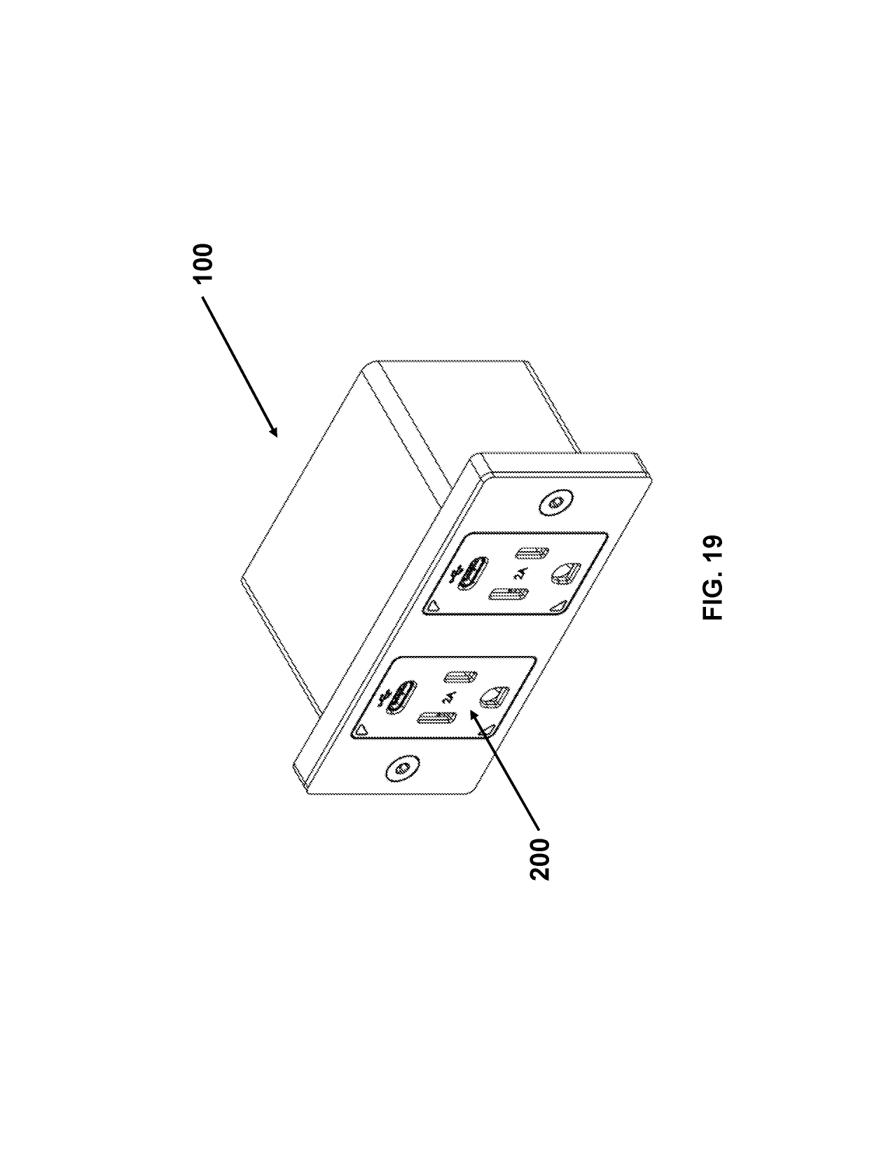

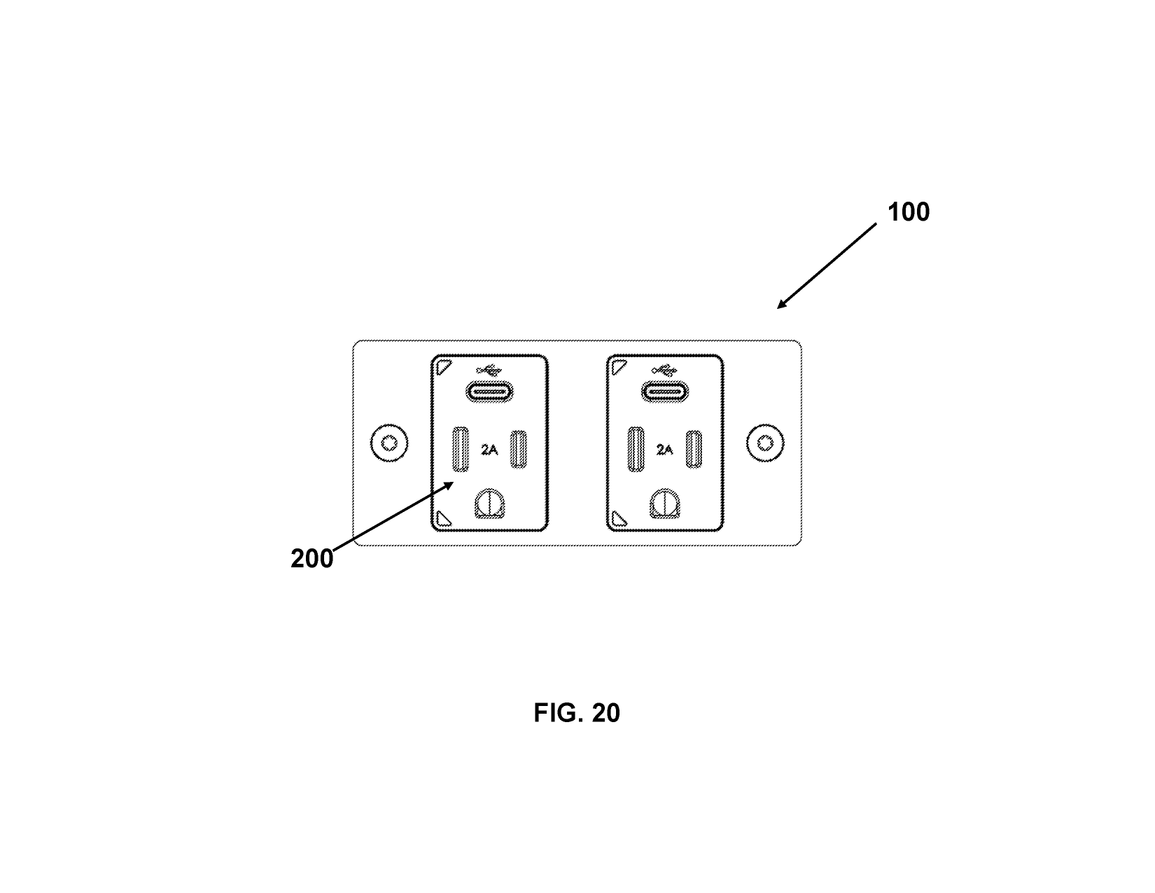

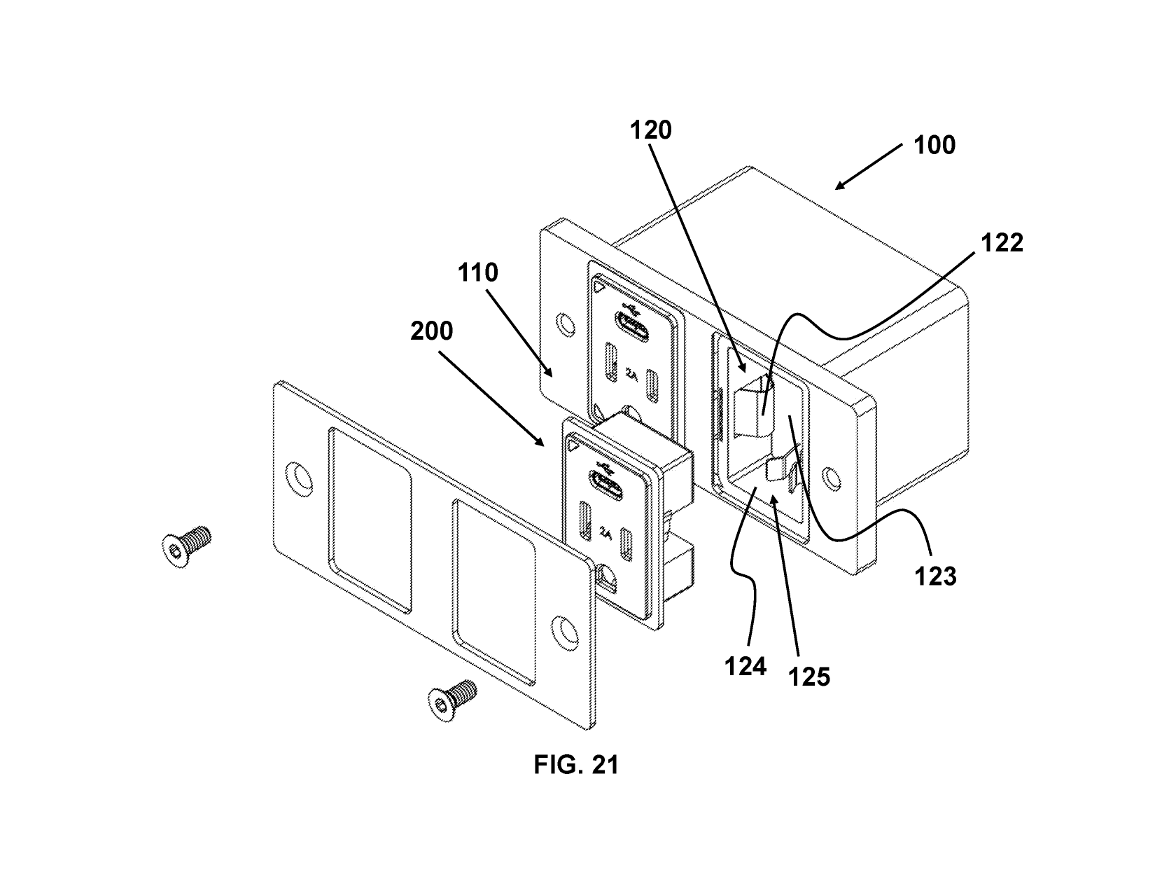

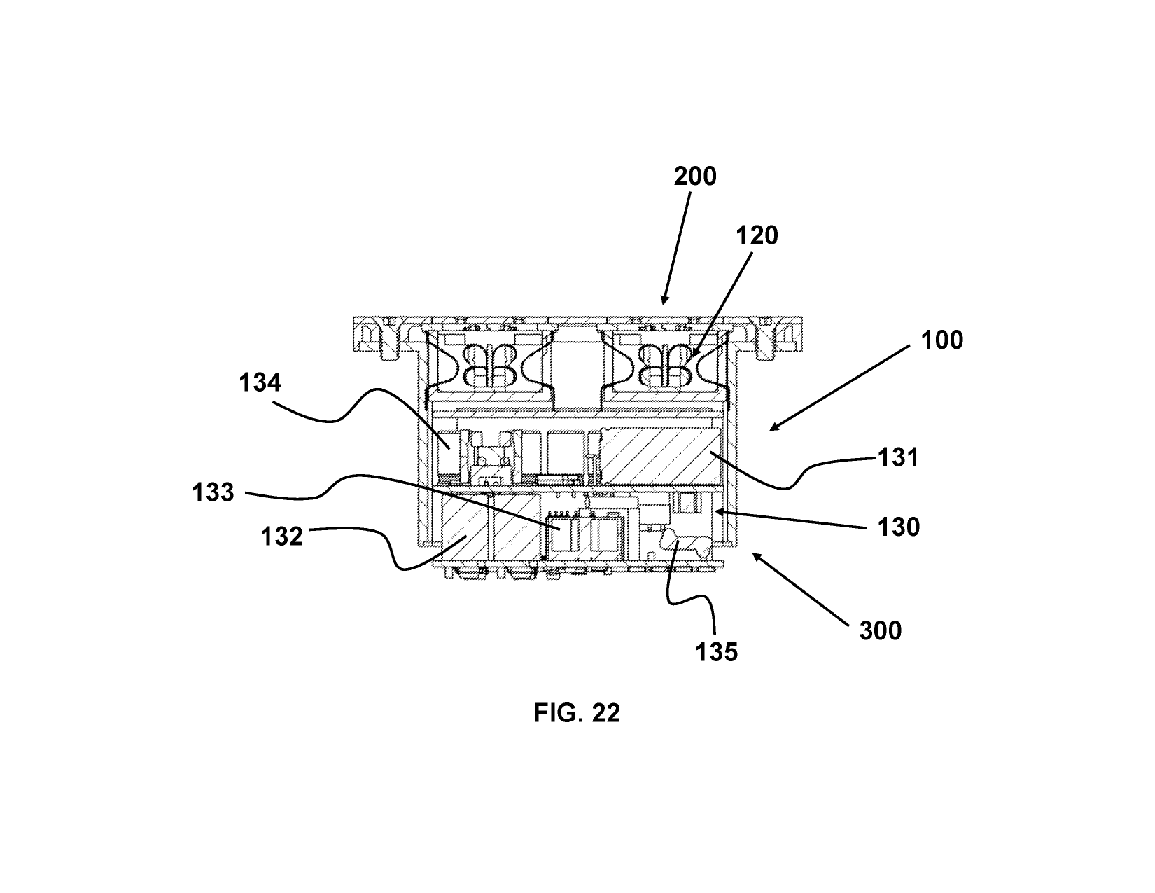

Referring now to FIGS. 19-23, another embodiment of an electrical outlet assembly 100 is illustrated. The electrical outlet 100 comprises two electrical outlets 200 adapted to receive an electrical plug 400. The electrical outlet assembly 100 further comprises a controller 136 in data communication with the electrical outlets 200. The electrical outlet assembly 100 further comprises a base portion 110. The base portion 110 may comprise a recess 120. The base portion 110 further comprises at least two electrical connectors 122 connected to the controller 136. The electrical outlet 200 comprises at least two openings or passages 231, each opening or passage 231 comprising a conductive portion 240 electrically and connected to the controller 136. The controller is configured to measure impedance in the conductive portion 240 of the electrical outlet and to power the two electrical connectors 122 when the measured impedance exceeds a predetermined impedance level.

The electrical outlet assembly 100 may comprise an electric relay 138 connected to the logic module 133 and the electrical connectors 122. The electric relay 138 is operable to supply high-voltage or operative voltage the two electrical connectors 122 when the detected impedance exceeds the predetermined impedance level. Otherwise, no voltage or a low voltage is supplied to the connectors 122. As such, one tampering with the outlet assembly 100 may not receive an electrical discharge of a high voltage if contacting the connectors 122, such as when inserting a metallic object within the passages 231. The operative voltage is provided to the connectors 122 only when the impedance is detected on the conductive portions 240. The conductive portions 240 are typically powered with a low voltage also referred as a detection voltage allowing detection of a level of impedance on the conductive portions 240.

As discussed above, the conductive portion may comprise a top section 241 and a bottom section 242. As such, the logic module 133 may being configured to detect a first level of impedance in the top section 241 and a second level of impedance in the bottom section 242 of the conductive portion 240, the second level of impedance exceeding a predetermined level of impedance being indicative of the electrical plug being fully inserted in the electrical outlet and the first level of impedance exceeding the predetermined level of impedance being indicative of the electrical plug being partially inserted in the electrical outlet 100.

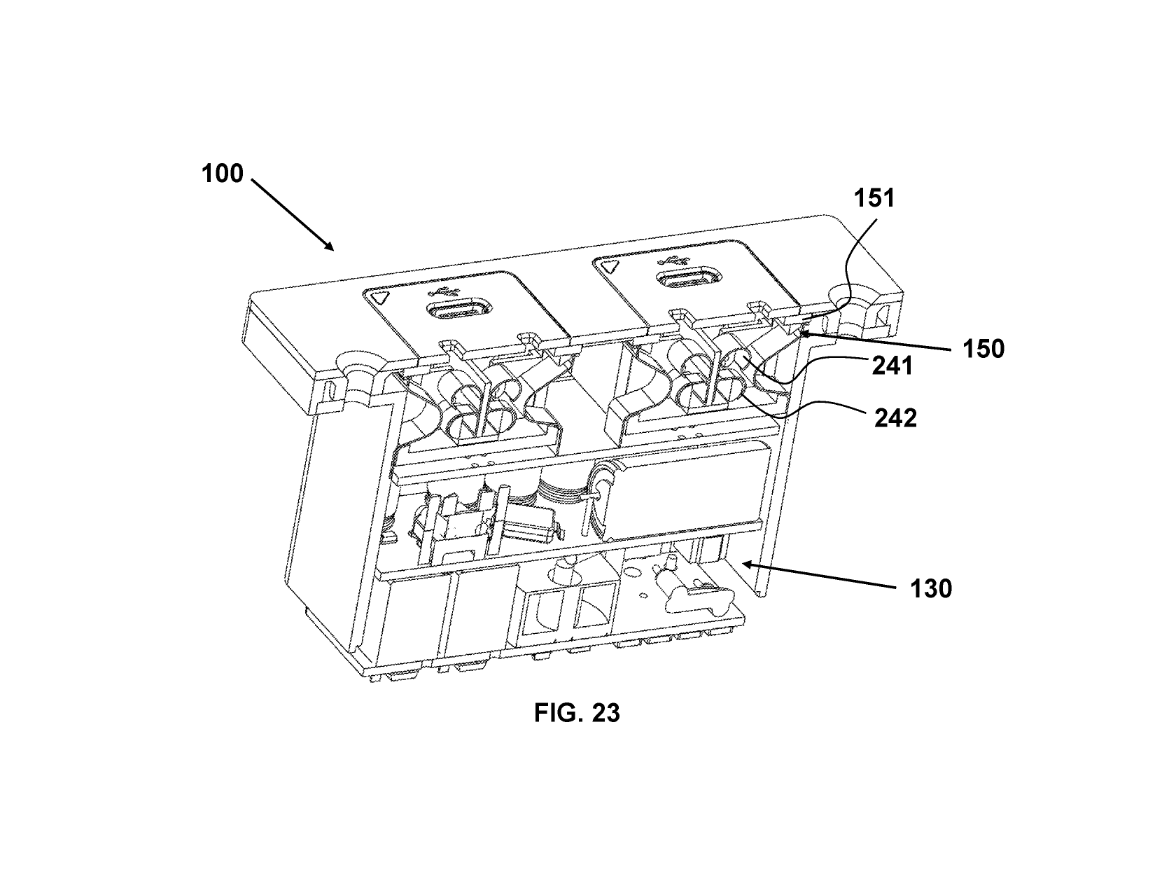

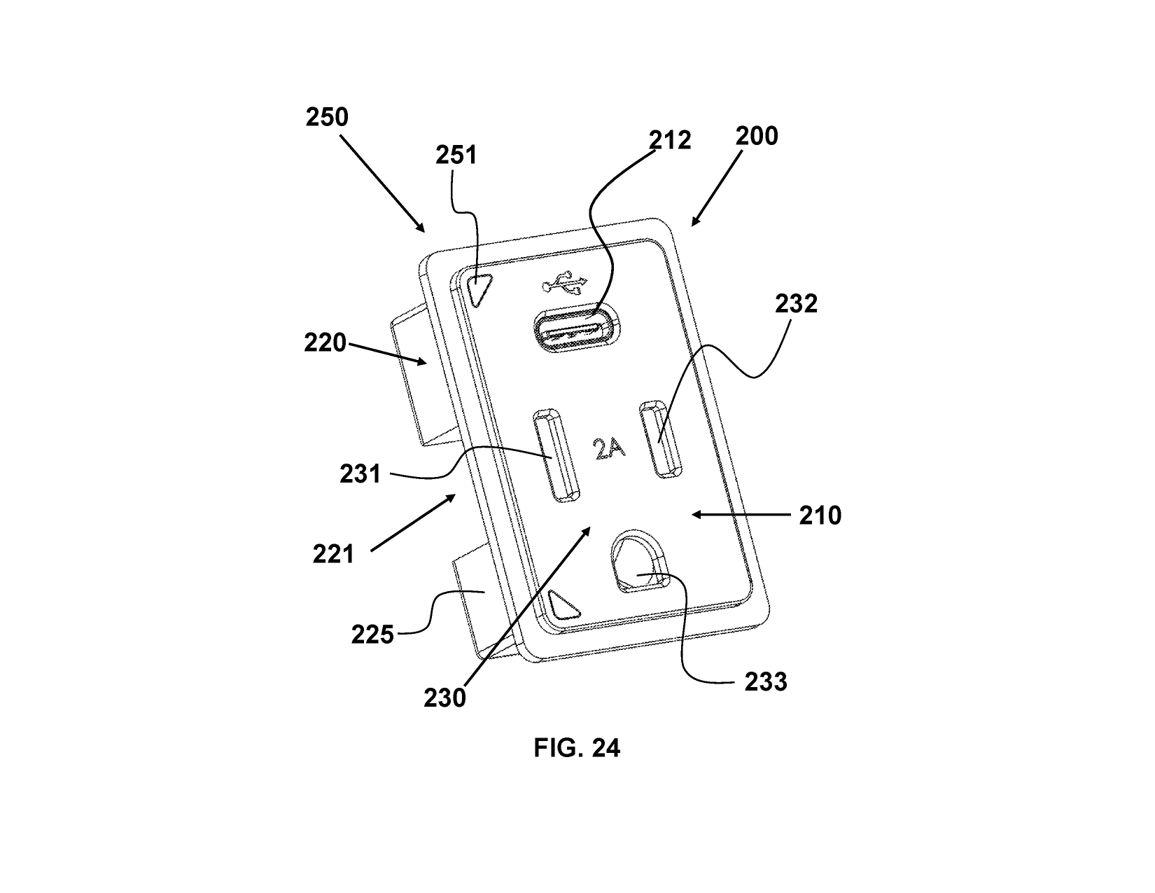

Referring to FIG. 23, the top covering portion or body portion 110 may comprise a locking mechanism 150 adapted to maintain the modular outlet 200 to the outlet assembly 100. The locking mechanism 150 may be embodied as a resilient clip 151 pushing against a portion of the recess portion 120 or of a wall 124 of the recess portion 120. Still referring to FIG. 23, the top and bottom sections 241 and 242 may be embodied as curved conductive plates. The electric connectors 122 may also be embodied as curved conductive plates to allow contacting the prong of the electrical plug 400 while being inserted in the passage 231 and in the recess portion 221 of the modular outlet 200.Referring now to FIGS. 24 to 27, an embodiment of a modular electrical outlet 200 is illustrated. The modular electrical outlet 200 generally comprises a top portion 210 and a body portion 220. The top portion 210 may comprise a USB-C port 212 and an electrical plug receptacle 230, which comprises a first aperture 231, a second aperture 232, and a third aperture 233. The apertures 231, 232, and 233 are shaped to receive the live, neutral, and ground prongs of an electrical plug, respectively.

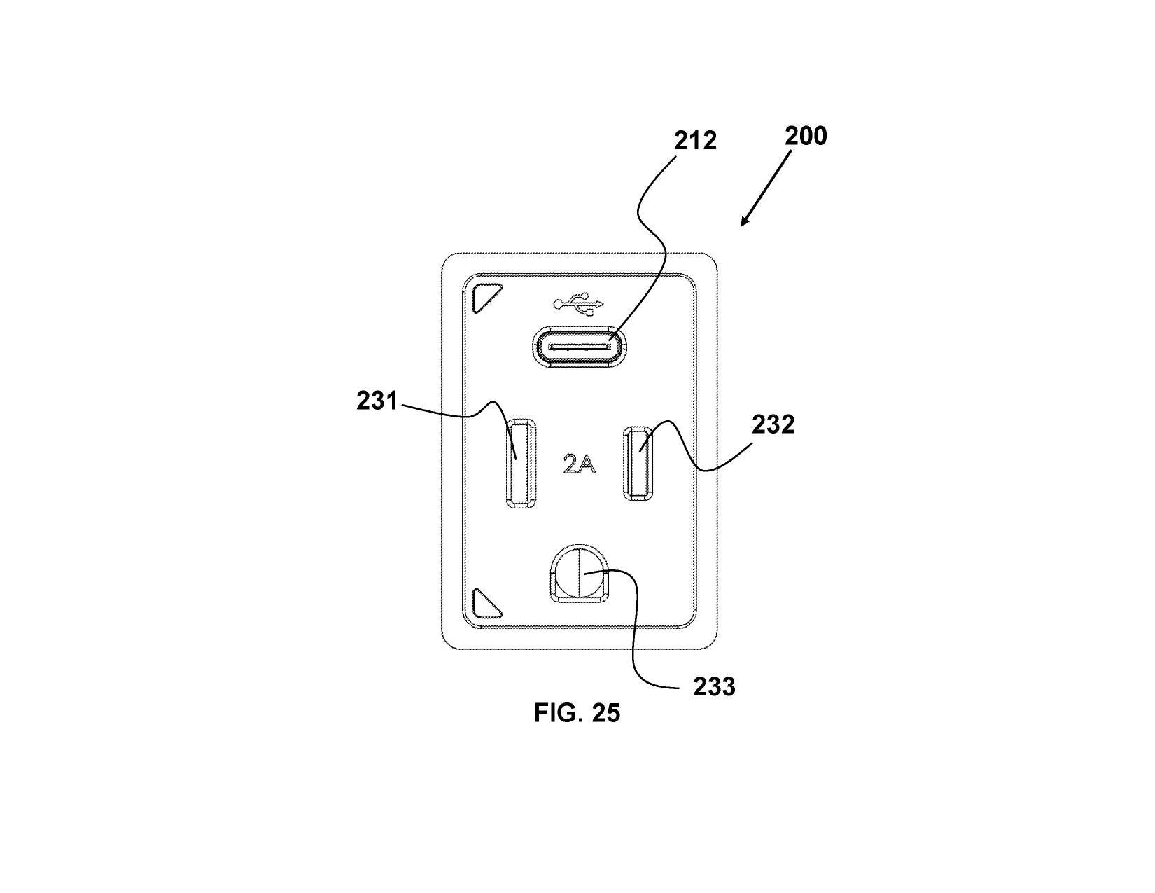

As shown in FIG. 24 and FIG. 25, the USB port 212 may be located above the electrical receptacle 230. The electrical receptacle 230 may be integrated into the front- facing surface of the top portion 210, and the three apertures 231, 232, and 233 are arranged in a standard plug configuration. The face of the modular outlet 200 also comprises a status display module 250, which includes a visual indicator 251, for example, a light-emitting element positioned near the top-left corner of the top portion 210.

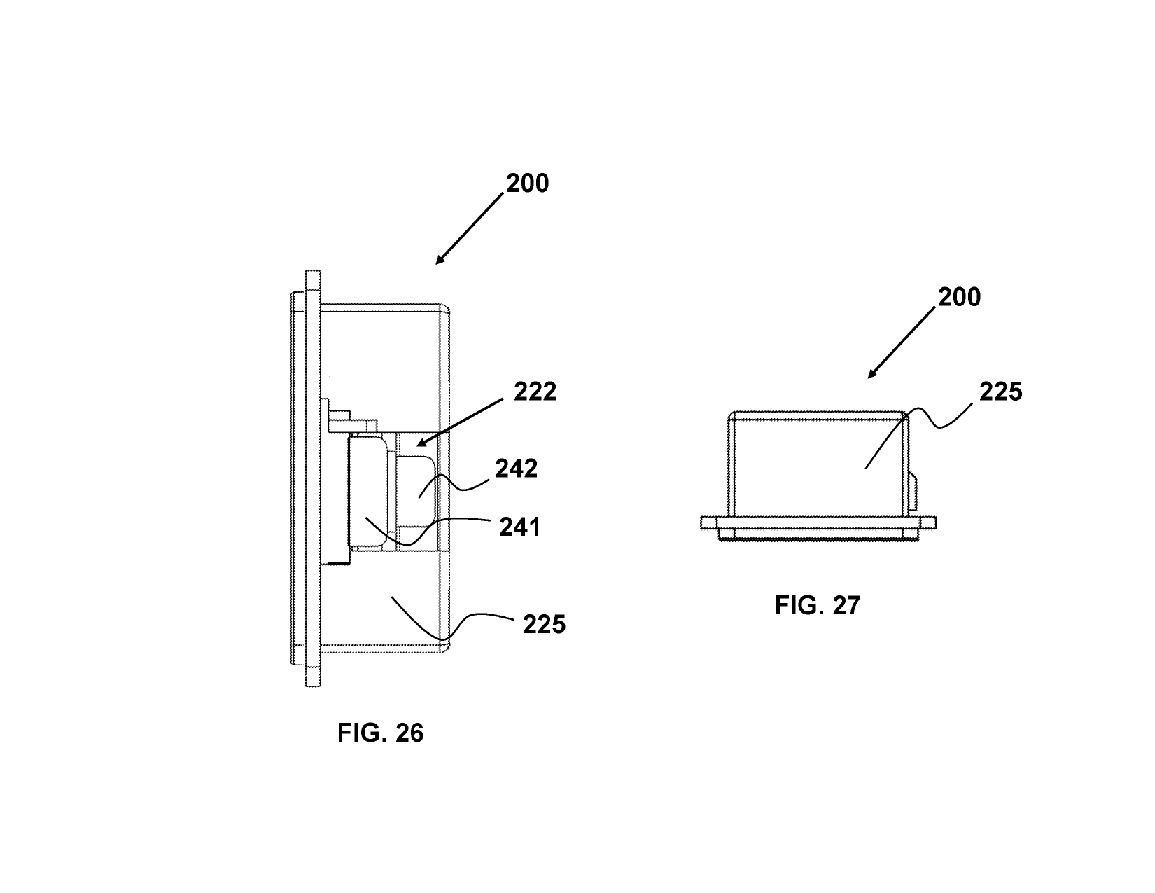

Referring now to FIGS. 26-27, the modular receptacle 200 comprises a passage 222 extending through the body portion 220. Within the passage 222, a top conductive section 241 and a bottom conductive section 242 may contact the prongs of the electrical plug 400 when inserted. As illustrated, the top section 241 and bottom section 242 are spaced apart vertically to contact the prong of an electrical plug at different insertion depths. The rear portion 225 generally surrounds and supports the conductive structure within the body portion 220.

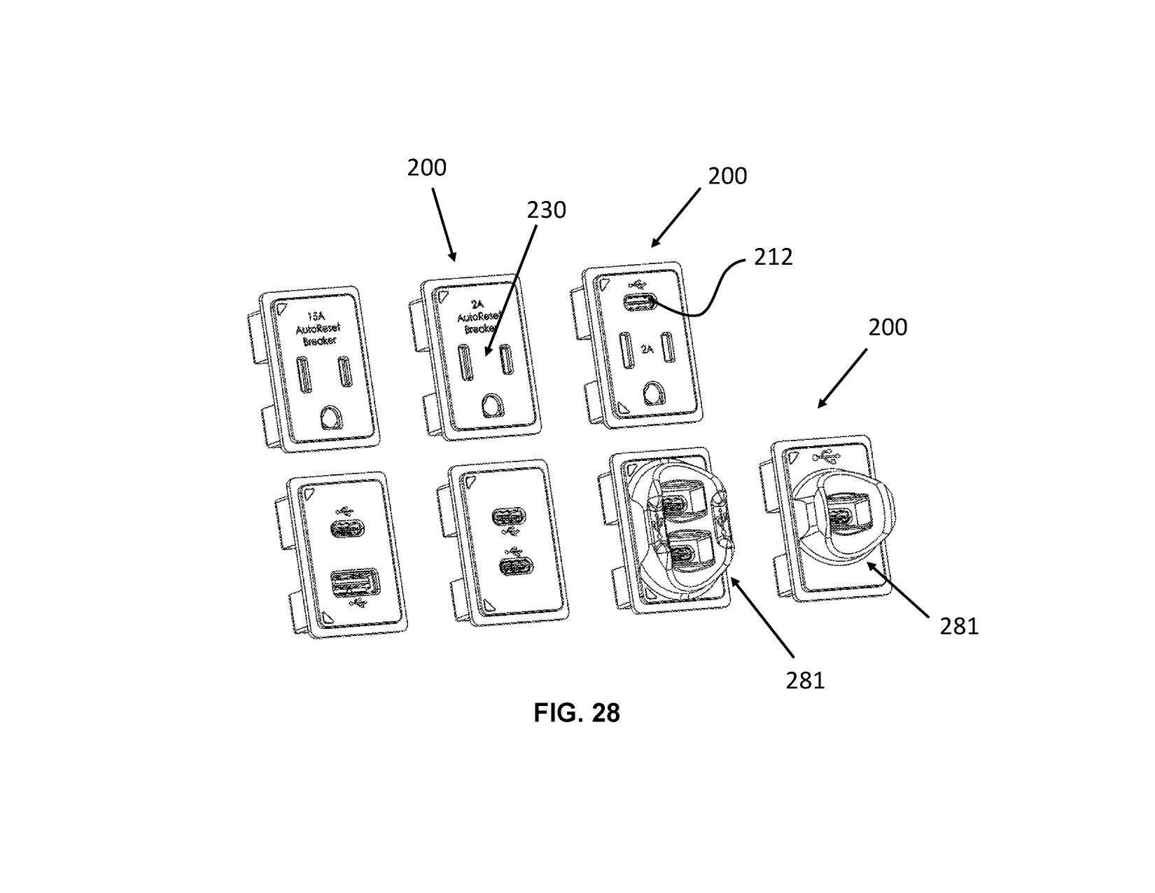

Referring now to FIG. 28, additional embodiments of modular electrical receptacles 200 are illustrated. Each receptacle 200 is configured to be removably inserted into a standard recess of the outlet assembly and demonstrates variations in functionality and port arrangements. Some receptacles 200 comprise a standard electrical socket 230 labeled with different current ratings such as "15A AutoReset Breaker" and "2A AutoReset Breaker." Other receptacles combine the electrical socket 230 with a USB port 212 or a pair of USB- C ports 212, allowing simultaneous access to high-voltage and low-voltage connections. Additional embodiments include receptacles comprising dual vertically or horizontally arranged USB ports 212. Some embodiments may further comprise a protective casing 281 integrated into the modular housing 220 and around the ports 212 or sockets 230. Understandingly, a modular electrical receptacle may be used for different functions and/or provide any other functionality which may be used in association with an electrical outlet.

A method for maintaining the modular electrical outlet assembly 100 is also provided. The method may comprise removing the modular receptacle 200 from the recess 120 of the base portion 110 and inspecting and cleaning the internal passages 221 , 222, and 223 of the receptacle 200 to remove foreign objects or debris which may be stuck inside. The modular receptacle 200 may include first, second, and third apertures 231, 232, and 233 aligned with the corresponding passages, and the cleaning step may include clearing each aperture individually or pushing objects entirely through the body portion 220 of the receptacle. After cleaning, the modular receptacle 200 may be reinserted into the recess 120, where resilient electrical connectors 122 within the recess are brought into contact with corresponding conductors in the receptacle to restore functionality. If the receptacle 200 is found to be non-functional or damaged, it may be replaced with a new modular receptacle 200. In some embodiments, the passages 221, 222, and 223 may extend fully through the body portion 220 to facilitate inspection and cleaning.

While illustrative and presently preferred embodiments of the invention have been described in detail hereinabove, it is to be understood that the inventive concepts may be otherwise variously embodied and employed and that the appended claims are intended to be construed to include such variations except insofar as limited by the prior art.

1. A tamper-proof electrical outlet assembly comprising:
a controller;
a base portion comprising:
at least two electrical connectors to an operative voltage source; and
an electrical outlet comprising at least two passages, each passage comprising a conductive portion electrically connected to the electrical connectors and connected to the controller;
the controller being configured to detect:
insertion of any of the blades of an electric plug in one of the passages of the electrical outlet; and
insertion of two blades of an electric plug in two of the passages of the electrical outlet;
the controller being further configured to power the two electrical connectors with the operative voltage when the insertion of the two blades of the electric plug is detected.

2. The electrical outlet assembly of claim 1 further comprising an electric relay connected to the controller and the electrical connectors, the relay being operable to supply the operative voltage to the two electrical connectors when the insertion of two blades of an electric plug is detected.

3. The electrical outlet assembly of claim 1, the controller being configured to measure impedance in the conductive portion of the electrical outlet and to power the two electrical connectors when the measured impedance varies from a predetermined impedance level.

4. The electrical outlet assembly of claim 1, the conductive portion of each passage comprising a top section and a bottom section, the controller being configured to detect depth of insertion of a blade of an electric plug based on detected presence of the blade over the top and bottom sections.

5. The electrical outlet assembly of claim 1, the base portion comprising a recess comprising the electrical connectors, the electrical outlet being a removable module having a shape substantially matching a shape of the recess.

6. The electrical outlet assembly of claim 5, the removable module comprising at least two passages for receiving prongs of an electrical plug and shaped to allow contact of the receivable prongs with the electrical connectors and with the conductive portions.

7. The electrical outlet assembly of claim 5, the removable module comprising a body having recesses for allowing passage of the electrical connectors of the recess.

8. The electrical outlet assembly of claim 5, wherein the removable module is retained within the recess of the body by friction or locking engagement.

9. The electrical outlet assembly of claim 1, further comprising a top covering portion mountable to an electrical box, the top covering portion defining at least one receptacle opening.

10. The electrical outlet assembly of claim 5, wherein the removable module comprises a speaker and a microphone.

11. The electrical outlet assembly of claim 5, wherein the modular receptacle comprises an RFID reader and is configured to detect a plug having an RFID tag.

12. The modular electrical outlet assembly of claim 1, further comprising a bracket configured to mount the assembly to a bench, seat, or surface, the bracket comprising fastener apertures and a recess for receiving wires.

13. The modular electrical outlet assembly of claim 1 further comprising a wireless communication module configured as a network repeater.

14. A modular connector removably insertable in an electrical outlet assembly, the modular connector comprising:
at least two passages for receiving prongs of an electric plug;
recess portions comprising conductive portion, each of the recess portions being in communication with one of the passages and allowing contact of the receivable prongs with the conductive portion; and
one or more conducting terminal connected to the conductive portion and connectable to a controller.

15. The modular connector of claim 14 comprising a status indicator connected to the conducting terminal.

16. The modular connector of claim 14 further comprising a speaker and a microphone.

17. The modular connector of claim 14 further comprising a RFID reader configured to detect a plug having an RFID tag.

18. A method for selectively powering an electrical outlet assembly, the method comprising:
supplying a detection signal to a first conductive portion of the electrical outlet assembly;
detecting insertion of one or two blades of an electric plug between the first conductive portion and an electrical connector of the electrical outlet; and
supplying an operative voltage to the electrical connector when two blades are detected as being inserted in the electrical outlet.

19. The method of claim 18 further comprising detecting insertion of the blade of the inserted electric plug over a second conductive portion of the electrical outlet assembly, the detection of the insertion on the first and second conductive portions being indicative of the blade being fully inserted.

20. The method of claim 18 further comprising:
detecting insertion of a first of the blades of the inserted electric plug;
detecting insertion of a second of the blades of the inserted electric plug;
measuring duration between the insertion of the first blade and the insertion of the second blade; and
supplying the operative voltage to the electrical connector if the measured duration is below a predetermined duration.
